(19) United States
(12) Patent Application Publication
(10) Pub. No.: US 2025/0386539 A1
(43) Pub. Date: Dec. 18, 2025

(54) INTEGRATED CIRCUIT DEVICE

(71) Applicant: Samsung Electronics Co., Ltd., Suwon-si (KR)

(72) Inventors: Dongwoo KIM, Suwon-si (KR); Chulsung KIM, Suwon-si (KR); Hyunwoo KIM, Suwon-si (KR); Donghyun ROH, Suwon-si (KR); Taeyeon SHIN, Suwon-si (KR)

(73) Assignee: Samsung Electronics Co., Ltd., Suwon-si (KR)

(21) Appl. No.: 18/980,133

(22) Filed: Dec. 13, 2024

(30) Foreign Application Priority Data
Jun. 18, 2024 (KR) 10-2024-0079095

(51) Int. Cl. H10D 30/00; H10D 30/01

(52) U.S. Cl. CPC H10D 30/502; H10D 30/0191; H10D 30/0198

(57) ABSTRACT

An integrated circuit device includes a channel region, a gate line surrounding the channel region, a source/drain region contacting the channel region, and a backside via contact passing through a portion of the source/drain region in a vertical direction from a back side of the source/drain region. The source/drain region includes a bottom epitaxial layer protruding from a bottom surface of the source/drain region, a blocking epitaxial layer contacting the channel region and the bottom epitaxial layer, and a main epitaxial layer filling a space defined by the blocking epitaxial layer. A first dopant concentration of the bottom epitaxial layer is greater than a second dopant concentration of the blocking epitaxial layer and is greater than or equal to a third dopant concentration of the main epitaxial layer, and the backside via contact passes through at least a portion of the bottom epitaxial layer in the vertical direction.

### CROSS-REFERENCE TO RELATED APPLICATION

This application is based on and claims priority under 35 U.S.C. § 119 to Korean Patent Application No. 10-2024-0079095, filed on Jun. 18, 2024, in the Korean Intellectual Property Office, the disclosure of which is incorporated by reference herein in its entirety.

### BACKGROUND

Inventive concepts relate to an integrated circuit (IC) device, and more particularly, to an IC device including a field-effect transistor (FET).

The downscaling of IC devices has rapidly progressed due to the development of electronic technology, and such highly downscaled IC devices expect having not only a high operating speed but also high operating accuracy. Accordingly, a technique of introducing a backside contact structure having a stable arrangement structure within a relatively small area has been proposed. It is desirable to develop an IC device including a backside contact structure, which is capable of improving the performance and reliability of a field-effect transistor (FET) by improving the reliability of an electrical contact between the backside contact structure and a source/drain region.

### SUMMARY

Inventive concepts provide an integrated circuit (IC) device, which may improve the performance and/or reliability of a field-effect transistor (FET) by improving the reliability of an electrical contact between a backside contact structure and a source/drain region.

According to some example embodiments, there is provided an IC device including a channel region, a gate line surrounding the channel region, a source/drain region adjacent to the gate line in a first lateral direction, the source/drain region contacting the channel region, and a backside via contact passing through a portion of the source/drain region in a vertical direction from a back side of the source/drain region, wherein the source/drain region includes a semiconductor layer including a dopant, and the source/drain region including a bottom epitaxial layer protruding from a bottom surface of the source/drain region toward a central portion of the source/drain region in the vertical direction, a blocking epitaxial layer contacting each of the channel region and the bottom epitaxial layer, and a main epitaxial layer filling a space defined by the blocking epitaxial layer on the bottom epitaxial layer, wherein a first dopant concentration of the bottom epitaxial layer is greater than a second dopant concentration of the blocking epitaxial layer and is greater than or equal to a third dopant concentration of the main epitaxial layer, and the backside via contact passes through at least a portion of the bottom epitaxial layer in the vertical direction.

Alternatively or additionally according to some example embodiments, there is provided an IC device including a plurality of channel regions apart from each other in a first lateral direction, a plurality of gate lines surrounding the plurality of channel regions, each gate line extending lengthwise in a second lateral direction, wherein the second lateral direction is perpendicular to the first lateral direction, a plurality of source/drain regions, each of which is between two adjacent ones of the plurality of gate lines, and a backside via contact passing through a portion of a first source/drain region in a vertical direction from a back side of a first source/drain region, wherein the first source/drain region is selected from the plurality of source/drain regions, wherein each of the plurality of source/drain regions includes a semiconductor layer including a dopant, and each of the plurality of source/drain regions including a bottom epitaxial layer protruding from a bottom surface of a corresponding one of the plurality of source/drain regions toward a central portion thereof in the vertical direction, a blocking epitaxial layer contacting a channel region adjacent thereto in the first lateral direction, from among the plurality of channel regions, and a main epitaxial layer filling a space defined by the blocking epitaxial layer on the bottom epitaxial layer, wherein, in each of the plurality of source/drain regions, a first dopant concentration of the bottom epitaxial layer is greater than a second dopant concentration of the blocking epitaxial layer and is greater than or equal to a third dopant concentration of the main epitaxial layer, and the backside via contact passes through at least a portion of the bottom epitaxial layer included in the first source/drain region in the vertical direction.

Alternatively or additionally according to some example embodiments, there is provided an IC device including a plurality of channel regions apart from each other in a first lateral direction, a plurality of gate lines respectively surrounding the plurality of channel regions, each gate line extending lengthwise in a second lateral direction, wherein the second lateral direction is perpendicular to the first lateral direction, a plurality of source/drain regions, each of which is between two adjacent ones of the plurality of gate lines, a frontside insulating structure covering a top surface of a front side of each of the plurality of source/drain regions, a backside via contact passing through a portion of a first source/drain region in a vertical direction from a back side of the first source/drain region, wherein the first source/drain region is selected from the plurality of source/drain regions, a backside metal silicide film between the first source/drain region and the backside via contact, a frontside source/drain contact passing through the frontside insulating structure in the vertical direction, the frontside source/drain contact passing through a portion of a second source/drain region in the vertical direction from a front side of the second source/drain region, wherein the second source/drain region is selected from the plurality of source/drain regions and apart from the first source/drain region, a frontside metal silicide film between the second source/drain region and the frontside source/drain contact, wherein each of the plurality of source/drain regions includes a semiconductor layer including a dopant, and each of the plurality of source/drain regions including a bottom epitaxial layer protruding from a bottom surface of a corresponding one of the source/drain regions toward a central portion thereof in the vertical direction, the bottom epitaxial layer having a first dopant concentration, a blocking epitaxial layer contacting each of the bottom epitaxial layer and a channel region adjacent to the blocking epitaxial layer in the first lateral direction, from among the plurality of channel regions, the blocking epitaxial layer having a second dopant concentration, wherein the second dopant concentration is lower than the first dopant concentration, and a main epitaxial layer filling a space defined by the blocking epitaxial layer on the bottom epitaxial layer, the main epitaxial layer having a third dopant concentration, wherein the third dopant concentration is lower than or equal to the first dopant concentration, wherein the backside via contact and the backside metal silicide film pass through at least a portion of the bottom epitaxial layer included in the first source/drain region in the vertical direction, and the frontside source/drain contact and the frontside metal silicide film are apart from the bottom epitaxial layer included in the second source/drain region in the vertical direction.

### BRIEF DESCRIPTION OF THE DRAWINGS

Some example embodiments will be more clearly understood from the following detailed description taken in conjunction with the accompanying drawings in which:

FIG. 1 is a plan view of a cell block of an integrated circuit (IC) device according to some example embodiments;

FIG. 2 is a plan layout diagram of an IC device according to some example embodiments;

FIG. 3A is a cross-sectional view taken along line X1-X1′ of FIG. 2;

FIG. 3B is a cross-sectional view taken along line Y1-Y1′ of FIG. 2;

FIG. 3C is a cross-sectional view taken along line Y2-Y2′ of FIG. 2;

FIG. 3D is an enlarged cross-sectional view of portion “EX1” of FIG. 3A;

FIG. 3E is an enlarged cross-sectional view of portion “EX2” of FIG. 3C;

FIGS. 4 to 9 are each a cross-sectional view of an IC device according to some example embodiments;

FIG. 10 is a cross-sectional view of an IC device according to some example embodiments;

FIGS. 11A to 29B are cross-sectional views of a process sequence of a method of manufacturing an IC device, according to some example embodiments, wherein FIGS. 11A, 12A, 13A, 14A, 15A, 16, 17A, 18A, 19A, 20A, 21A, 22A, 23A, 24A, 25A, 26, 27A, 28A, and 29A are cross-sectional views of example cross-sectional structures of a portion corresponding to a cross-section taken along line X1-X1′ of FIG. 2, according to the process sequence, FIGS. 11B, 12B, 13B, 14B, 18B, 19B, 20B, 21B, 22B, 23B, 24B, and 25B are cross-sectional views of example cross-sectional structures of a portion corresponding to a cross-section taken along line Y1-Y1′ of FIG. 2, according to the process sequence, and FIGS. 14C, 15B, 17B, 18C, 22C, 23C, 24B, 27B, 28B, and 29B are cross-sectional views of example cross-sectional structures of a portion corresponding to a cross-section taken along line Y2-Y2′ of FIG. 2, according to a process sequence; and

FIGS. 30A to 33 are cross-sectional views of a process sequence of a method of manufacturing an IC device, according to some example embodiments, wherein FIGS. 30A, 31A, 32, and 33 are cross-sectional views of example cross-sectional structures of a portion corresponding to a cross-section taken along line X1-X1′ of FIG. 2, according to the process sequence, and FIGS. 30B and 31B are cross-sectional views of example cross-sectional structures of a portion corresponding to a cross-section taken along line Y1-Y1′ of FIG. 2, according to the process sequence.

### DETAILED DESCRIPTION OF SOME EXAMPLE EMBODIMENTS

Hereinafter, some example embodiments will be described in detail with reference to the accompanying drawings. The same reference numerals are used to denote the same elements in the drawings, and repeated descriptions thereof will be omitted.

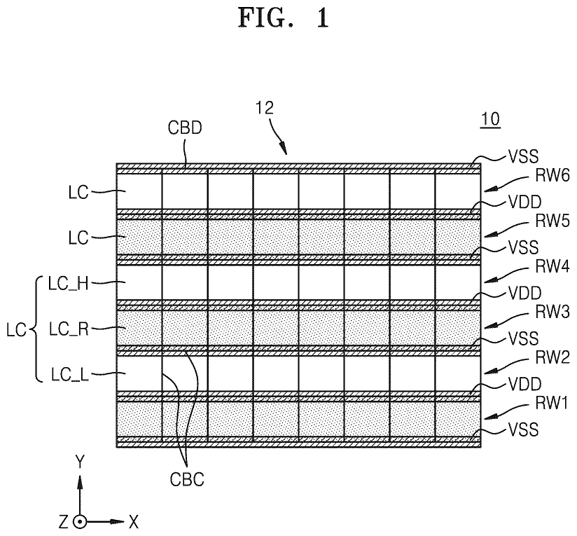

FIG. 1 is a plan layout diagram of some components of an integrated circuit (IC) device 100 according to some example embodiments.

FIG. 1 is a plan view of a cell block 12 of an integrated circuit (IC) device 10 according to some example embodiments.

Referring to FIG. 1, the cell block 12 of the IC device 10 may include a plurality of cells LC, which include circuit patterns configured to constitute various circuits. The plurality of cells LC may be arranged in a matrix form in a widthwise direction (X direction in FIG. 1) and a height direction (Y direction in FIG. 1) in the cell block 12.

Each of the plurality of cells LC may include a circuit pattern having a layout designed according to a place-and-route (PnR) technique to perform at least one logic function. The plurality of cells LC may perform various logic functions. In some example embodiments, the plurality of cells LC may include a plurality of standard cells or a plurality of IP blocks. In some example embodiments, at least some of the plurality of cells LC may perform the same logic function. Alternatively or additionally, in some example embodiments, at least some of the plurality of cells LC may perform different logic functions. Each of the plurality of logic cells LC may have the same size and/or shape, or, alternatively, at least one of the plurality of logic cells LC may have a different size and/or shape than others of the plurality of logic cells LC.

The plurality of cells LC may include various kinds of logic cells including a plurality of circuit elements. For example, each of the plurality of logic cells LC may include an AND gate, a NAND gate, an OR gate, a NOR gate, an exclusive OR (XOR) gate, an exclusive NOR (XNOR) gate, an inverter (INV), an adder (ADD), a buffer (BUF), a delay (DLY), a filter (FIL), a multiplexer (MXT/MXIT), an OR/AND/INVERTER (OAI) gate, an AND/OR (AO) gate, an AND/OR/INVERTER (AOI) gate, a D-flip-flop, a reset flip-flop, a master-slave flip-flop, a latch, or a combination thereof, without being limited thereto.

In the cell block 12, at least some of the plurality of cells LC that forms one row RW1, RW2, RW3, RW4, RW5, or RW6 in the widthwise direction (X direction in FIG. 1) may have the same width as each other. Also, at least some of the plurality of cells LC that forms one row RW1, RW2, RW3, RW4, RW5, or RW6 may have the same height as each other. However, inventive concepts are not limited to those illustrated in FIG. 1, and at least some of the plurality of cells LC that forms one row RW1, RW2, RW3, RW4, RW5, or RW6 may have different widths and/or heights from each other.

An area of each of the plurality of cells LC included in the cell block 12 of the IC device 10 may be defined by a cell boundary CBD. A cell boundary contact portion CBC where respective cell boundaries CBD of two cells LC that are adjacent to each other in the widthwise direction (X direction in FIG. 1) or the height direction (Y direction in FIG. 1), from among the plurality of cells LC, meet each other may be between the two adjacent cells LC.

In some example embodiments, from among the plurality of cells LC that form one row RW1, RW2, RW3, RW4, RW5, or RW6, two cells LC that are adjacent to each other in the widthwise direction may contact each other at the cell boundary contact portion CBC without a distance therebetween. Alternatively or additionally in some example embodiments, from among the plurality of cells LC that form one row RW1, RW2, RW3, RW4, RW5, or RW6, two cells LC that are adjacent to each other in the widthwise direction may be a distance (such as a predetermined distance) apart from each other.

In some example embodiments, from among the plurality of cells LC that form one row RW1, RW2, RW3, RW4, RW5, or RW6, two adjacent cells LC may perform the same function as each other. In this case, the two adjacent cells LC may have the same structure as each other. In some example embodiments, from among the plurality of cells LC that form one row RW1, RW2, RW3, RW4, RW5, or RW6, two adjacent cells may perform different functions from each other.

In some example embodiments, one cell LC, which is selected from the plurality of cells LC included in the cell block 12 of the IC device 10, may have a symmetrical structure to another cell LC, which is adjacent to the selected cell LC in the height direction (Y direction in FIG. 1), about the cell boundary contact portion CBC therebetween. For example, a reference logic cell LC_R in a third row RW3 may have a symmetrical structure to a lower logic cell LC_L in a second row RW2 about the cell boundary contact portion CBC therebetween. Also, the reference logic cell LC_R in the third row RW3 may have a symmetrical structure to an upper logic cell LC_H in a fourth row RW4 about the cell boundary contact portion CBC therebetween. Although FIG. 1 illustrates an example in which the cell block 12 including six rows RW1, RW2, . . . , and RW6, inventive concepts are not limited thereto. The cell block 12 may include various numbers of rows, which are selected as needed, and one row may include various numbers of cells, which are selected as needed or desired.

A selected one of a plurality of ground lines VSS and a plurality of power lines VDD may be between a plurality of rows (e.g., RW1, RW2, RW3, RW4, RW5, and RW6), each of which includes a plurality of cells LC arranged in a line in the widthwise direction (X direction in FIG. 1). The plurality of ground lines VSS and the plurality of power lines VDD may each extend in a first lateral direction (X direction) and may be alternately arranged apart from each other in a second lateral direction (Y direction). The second lateral direction (Y direction) may be perpendicular to the first lateral direction (X direction). Accordingly, the plurality of ground lines VSS and the plurality of power lines VDD may each overlap the cell boundary CBD of the cell LC in the second lateral direction (Y direction).

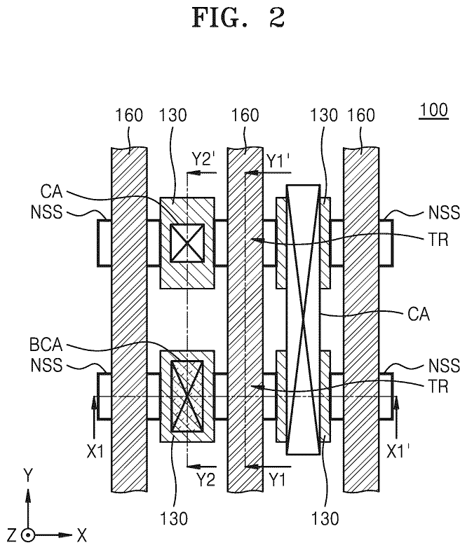

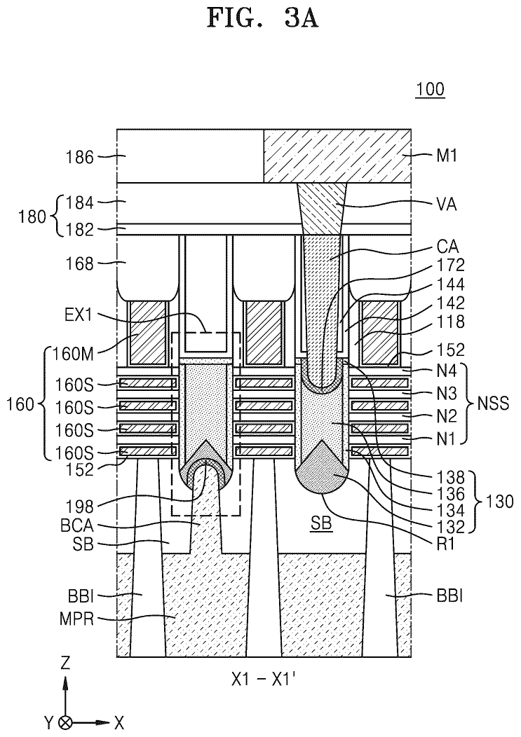

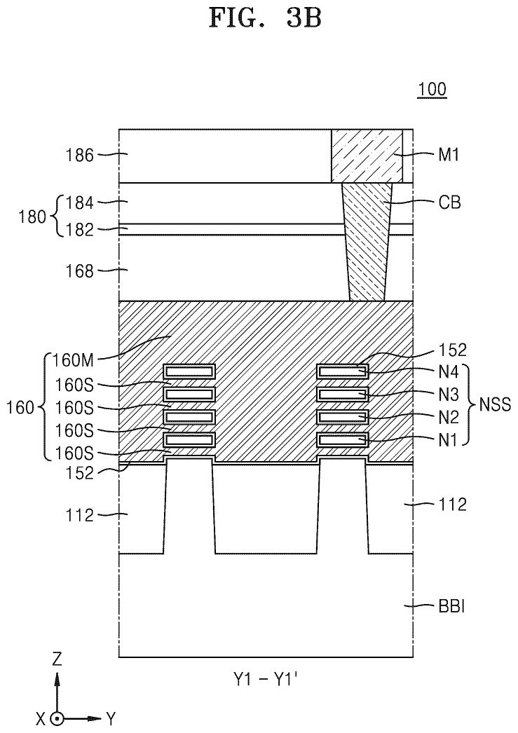

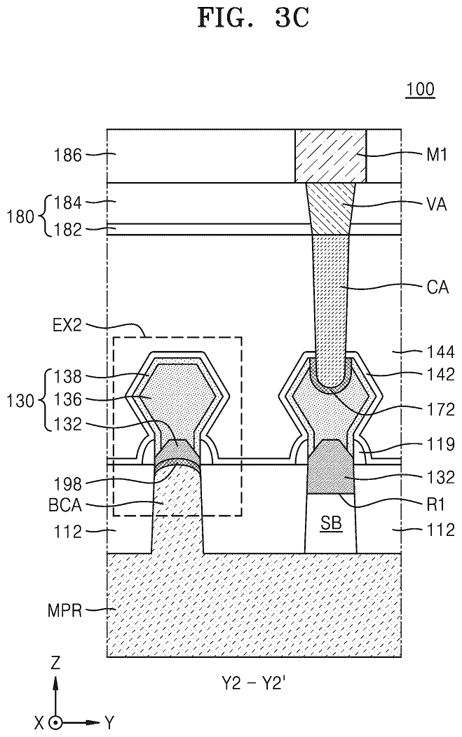

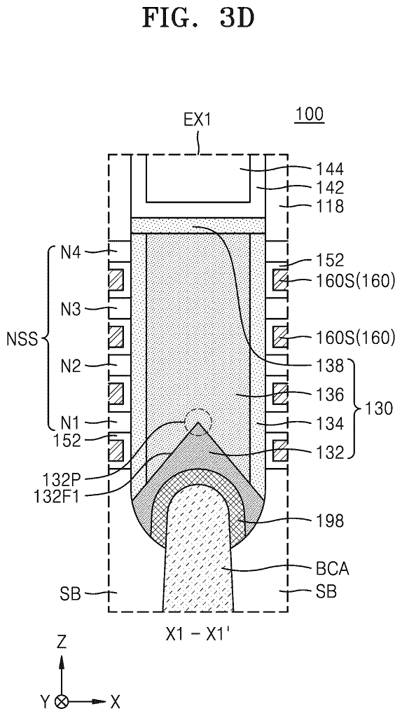

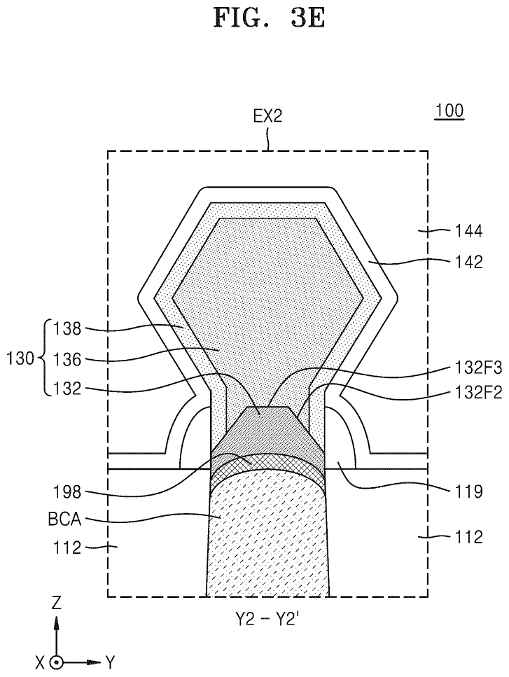

FIG. 2 is a plan layout diagram of an IC device 100 according to some example embodiments. FIG. 3A is a cross-sectional view taken along line X1-X1′ of FIG. 2. FIG. 3B is a cross-sectional view taken along line Y1-Y1′ of FIG. 2. FIG. 3C is a cross-sectional view taken along line Y2-Y2′ of FIG. 2. FIG. 3D is an enlarged cross-sectional view of portion “EX1” of FIG. 3A. FIG. 3E is an enlarged cross-sectional view of portion “EX2” of FIG. 3C.

With reference to FIGS. 2 and 3A-3E, the IC device 100 including a field-effect transistor (FET) having a gate-all-around structure including a channel region of a nanowire or nanosheet type and a gate surrounding the channel region is described. Of the IC device 100, components shown in FIGS. 2 and 3A to 3E may constitute some of the plurality of cells LC shown in FIG. 1.

Referring to FIGS. 2 and 3A to 3E, the IC device 100 may include a plurality of nanosheet stacks NSS, a plurality of gate lines 160 surrounding the plurality of nanosheet stacks NSS, and a plurality of source/drain regions 130, each of which is between two adjacent ones of the plurality of gate lines 160. The plurality of gate lines 160, the plurality of nanosheet stacks NSS, and the plurality of source/drain regions 130 may constitute or correspond to a plurality of nanosheet transistors TR.

The plurality of nanosheet stacks NSS may be arranged apart from each other in a first lateral direction (X direction) and a second lateral direction (Y direction), which intersect with each other at an angle such as at right angles. Each of the plurality of nanosheet stacks NSS may include a first nanosheet N1, a second nanosheet N2, a third nanosheet N3, and a fourth nanosheet N4, which are sequentially stacked in a vertical direction (Z direction) and apart from each other. The vertical direction (Z direction) may be a direction perpendicular to each of the first lateral direction (X direction) and the second lateral direction (Y direction). As used herein, each of the nanosheet stack NSS and the first to fourth nanosheets N1, N2, N3, N4 included in the nanosheet stack NSS may be referred to as a channel region.

The plurality of gate lines 160 may be apart from each other in the first lateral direction (X direction) and may extend lengthwise in the second lateral direction (Y direction). The plurality of gate lines 160 may be arranged at a constant pitch; however, example embodiments are not limited thereto. Each of the plurality of gate lines 160 may surround the first to fourth nanosheets N1, N2, N3, and N4 included in the nanosheet stack NSS. Each of the plurality of gate lines 160 may be surrounded by a gate dielectric film 152.

Each of the plurality of source/drain regions 130 may be between two adjacent ones of the plurality of gate lines 160. A backside via contact BCA may be connected to some source/drain regions 130 (referred to as first source/drain regions) selected from the plurality of source/drain regions 130. The backside via contact BCA may pass through a lower portion of the source/drain region 130 in the vertical direction (Z direction) from a back side of a corresponding one of the source/drain regions 130.

A frontside source/drain contact CA may be connected to some other source/drain regions 130 (referred to as second source/drain regions) selected from the plurality of source/drain regions 130. The frontside source/drain contact CA may pass through an upper portion of the corresponding one of the source/drain regions 130 in the vertical direction (Z direction) from a front side of the source/drain region 130.

A top surface of a front side of each of the plurality of source/drain regions 130 may be covered by an insulating liner 142 and an inter-gate dielectric film 144. The insulating liner 142 and the inter-gate dielectric film 144 may constitute or be included in a frontside insulating structure. The top surface of the front side of each of the plurality of source/drain regions 130 may be in contact with the insulating liner 142 of the frontside insulating structure. The frontside source/drain contact CA may pass through the inter-gate dielectric film 144 and the insulating liner 142 of the frontside insulating structure in the vertical direction (Z direction) and pass through the upper portion of the corresponding one of the source/drain regions 130 in the vertical direction (Z direction).

As used herein, a bottom surface of a back side of each of the plurality of source/drain regions 130 may refer to a surface opposite to the top surface of the front side thereof in the vertical direction (Z direction). The bottom surface of the back side of the source/drain region 130 may be apart from the frontside insulating structure in the vertical direction (Z direction).

A backside metal silicide film 198 may be between the backside via contact BCA and the source/drain region 130 (referred to as the first source/drain region) that is connected to the backside via contact BCA, from among the plurality of source/drain regions 130. The backside via contact BCA may be configured to be connected to the corresponding one of the source/drain regions 130 through the backside metal silicide film 198.

A frontside metal silicide film 172 may be between the frontside source/drain contact CA and the source/drain region 130 (referred to as the second source/drain region) that is connected to the frontside source/drain contact CA, from among the plurality of source/drain regions 130. The frontside source/drain contact CA may be configured to be connected to the corresponding one of the source/drain regions 130 through the frontside metal silicide film 172.

Each of the plurality of source/drain regions 130 may include a bottom epitaxial layer 132, a blocking epitaxial layer 134, a main epitaxial layer 136, and a capping layer 138. In some example embodiments, the capping layer 138 may be omitted in each of or at least some of the plurality of source/drain regions 130.

In each of the plurality of source/drain regions 130, the bottom epitaxial layer 132 may have a shape protruding from a bottom surface of the corresponding one of the source/drain regions 130 toward a central portion thereof in the vertical direction (Z direction). As used herein, the bottom surface of the source/drain region 130 may refer to the bottom surface of the back side of the source/drain region 130 and refer to a surface of the source/drain region 130, which is apart from the frontside insulating structure in the vertical direction (Z direction).

In each of the plurality of source/drain regions 130, the blocking epitaxial layer 134 may be in contact with each of the first to fourth nanosheets N1, N2, N3, and N4 included in the nanosheet stack NSS, which is adjacent to the corresponding one of the source/drain regions 130 in the first lateral direction (X direction). In each of the plurality of source/drain regions 130, the main epitaxial layer 136 may fill a space defined by the blocking epitaxial layer 134 on the bottom epitaxial layer 132.

Each of the plurality of source/drain regions 130 may include a semiconductor layer including a dopant such as one or more of a Group III-type dopant and/or one or more of a Group V-type dopant and/or one or more of a Group-IV type dopant. In each of the plurality of source/drain regions 130, a dopant concentration of the bottom epitaxial layer 132 may be greater than a dopant concentration of each of the blocking epitaxial layer 134 and the capping layer 138 and be greater than or equal to a dopant concentration of the main epitaxial layer 136.

In some example embodiments, the IC device 100 may include a nanosheet transistor (refer to TR in FIG. 2) including a PMOS transistor. Each of the plurality of source/drain regions 130 may include a Si₁₋ₓGeₓ layer (here, x≠0) doped with a p-type dopant. In each of the plurality of source/drain regions 130, a germanium (Ge) content the bottom epitaxial layer 132 may be greater than a Ge content of each of the blocking epitaxial layer 134 and the capping layer 138 and be greater than or equal to a Ge content of the main epitaxial layer 136. For example, each of the plurality of source/drain regions 130 may include a Si₁₋ₓGeₓ layer (here, x≠0) doped with a p-type dopant. In each of the plurality of source/drain regions 130, a Ge content of the bottom epitaxial layer 132 may be in a range of about 45 atomic percent (at %) to about 70 at %, and a Ge content of the blocking epitaxial layer 134 may be in a range of about 3 at % to about 10 at %. A Ge content of the main epitaxial layer 136 may be in a range of about 40 at % to about 65 at %, and a Ge content of the capping layer 138 may be in a range of about 0 at % to about 10 at %.

When the IC device 100 includes a nanosheet transistor (refer to TR in FIG. 2) including a PMOS transistor and the plurality of source/drain regions 130 include a Si₁₋ₓGeₓ layer (here, x≠0) doped with a p-type dopant, in each of the plurality of source/drain regions 130, the concentration of the p-type dopants in the bottom epitaxial layer 132 may be greater than the concentration of the p-type dopants in each of the blocking epitaxial layer 134 and the capping layer 138 and be greater than or equal to the concentration of the p-type dopants in the main epitaxial layer 136. The p-type dopant may include at least one selected from boron (B) and gallium (Ga), without being limited thereto. A dopant concentration of boron may be greater than, less than, or equal to a dopant concentration of gallium.

For instance, the plurality of source/drain regions 130 may include boron (B) as the p-type dopant. In this case, in each of the plurality of source/drain regions 130, the dopant concentration of boron (B) in the bottom epitaxial layer 132 may be in a range of about 8×10²⁰ atoms/cm³ to about 3×10²¹ atoms/cm³, and the dopant concentration of boron in the blocking epitaxial layer 134 may be in a range of about 8×10¹⁸ atoms/cm³ to about 3×10¹⁹ atoms/cm³. The dopant concentration of boron in the main epitaxial layer 136 may be in a range of about 6×10²⁰ atoms/cm³ to about 2×10²¹ atoms/cm³, and the dopant concentration of boron in the capping layer 138 may be in a range of about 0 atoms/cm³ to about 3×10¹⁹ atoms/cm³.

In some example embodiments, the IC device 100 may include a nanosheet transistor (refer to TR in FIG. 2) including an NMOS transistor, and each of the plurality of source/drain regions 130 may include a silicon (Si) layer doped with an n-type dopant.

When the IC device 100 includes the nanosheet transistor (refer to TR in FIG. 2) including the NMOS transistor and each of the plurality of source/drain regions 130 includes a Si layer doped with an n-type dopant, in each of the plurality of source/drain regions 130, the concentration of the n-type dopants in the bottom epitaxial layer 132 may be greater than the concentration of the n-type dopants in each of the blocking epitaxial layer 134 and the capping layer 138 and be greater than the concentration of the n-type dopant in the main epitaxial layer 136. The n-type dopant may include at least one selected from phosphorus (P), arsenic (As), and antimony (Sb), without being limited thereto. A dopant concentration of each of phosphorus, arsenic, and antimony may be the same as each other, or a dopant concentration of at least one of phosphorus, arsenic, and antimony may be different from (greater than or less than) others of phosphorus, arsenic, and antimony.

For example, the plurality of source/drain regions 130 may include phosphorus (P) as the n-type dopant. In this case, in each of the plurality of source/drain regions 130, the dopant concentration of phosphorus (P) in the bottom epitaxial layer 132 may be in a range of about 8×10²⁰ atoms/cm³ to about 6×10²¹ atoms/cm³, and the dopant concentration of phosphorus in the blocking epitaxial layer 134 may be in a range of about 1×10¹⁸ atoms/cm³ to about 1×10¹⁹ atoms/cm³. The dopant concentration of phosphorus in the main epitaxial layer 136 may be in a range of about 1×10²¹ atoms/cm³ to about 4×10²¹ atoms/cm³, and the dopant concentration of phosphorus in the capping layer 138 may be in a range of about 1×10¹⁹ to about 5×10²⁰ atoms/cm³.

As shown in FIGS. 3A and 3D, the backside via contact BCA and the backside metal silicide film 198 may pass through a portion of the bottom epitaxial layer 132 of the corresponding one of the source/drain regions 130 in the vertical direction (Z direction). The backside metal silicide film 198 may be in contact with the bottom epitaxial layer 132 of the corresponding one of the source/drain regions 130. Accordingly, the backside via contact BCA may be configured to be connected to the corresponding one of the source/drain regions 130 through the backside metal silicide film 198. As described above, the backside metal silicide film 198 located between the backside via contact BCA and the source/drain region 130 may have a structure that contacts the bottom epitaxial layer 132, which has a highest dopant concentration in the source/drain region 130. As a result, a Schottky barrier height between the backside via contact BCA and the source/drain region 130 may be reduced, and thus, resistance between the backside via contact BCA and the source/drain region 130 may be reduced. Therefore, the electrical reliability of the IC device 100 may be improved by suppressing or reducing an increase in contact resistance between the backside via contact BCA and the source/drain region 130.

As shown in FIG. 3D, in each of the plurality of source/drain regions 130, the main epitaxial layer 136 may be in contact with each of the bottom epitaxial layer 132 and the blocking epitaxial layer 134. The bottom epitaxial layer 132 may include an upper surface that is inclined in a direction close to the top surface of the front side of the corresponding one of the source/drain regions 130 toward the central portion thereof in the first lateral direction (X direction), and the top surface of the bottom epitaxial layer 132 may include a first facet 132F1 having a {111} plane orientation.

As shown in FIG. 3E, the bottom epitaxial layer 132 may further include a second facet 132F2 and a third facet 132F3. The second facet 132F2 may be inclined in a direction close to the top surface of the front side of the corresponding one of the source/drain regions 130 toward the central portion thereof in the second lateral direction (Y direction). The third facet 132F3 may extend in the second lateral direction (Y direction). The second facet 132F2 of the bottom epitaxial layer 132 may have a {111} plane orientation, and the third facet 132F3 of the bottom epitaxial layer 132 may have a {100} plane orientation.

As shown in FIG. 3D, a portion of the first facet 132F1 of the bottom epitaxial layer 132 may be in contact with the blocking epitaxial layer 134, and another portion of the first facet 132F1 of the bottom epitaxial layer 132 may be in contact with the main epitaxial layer 136. The upper surface of the bottom epitaxial layer 132 may include a vertex portion 132P where two first facets 132F1 having different inclination directions meet each other. The main epitaxial layer 136 may include a portion that fills a corner space defined by the bottom epitaxial layer 132 and the blocking epitaxial layer 134 at a location adjacent to a portion where the bottom epitaxial layer 132 contacts the blocking epitaxial layer 134. The main epitaxial layer 136 may include a portion surrounding the vertex portion 132P of the bottom epitaxial layer 132.

As shown in FIG. 3A, the frontside source/drain contact CA may pass through the frontside insulating structure including the insulating liner 142 and the inter-gate dielectric film 144 in the vertical direction (Z direction), and the frontside source/drain contact CA and the frontside metal silicide film 172 may pass through a portion of the corresponding one of the source/drain regions 130 in the vertical direction (Z direction) from the front side of the corresponding one of the source/drain regions 130.

The frontside source/drain contact CA and the frontside metal silicide film 172 may be apart from the bottom epitaxial layer 132 of the corresponding one of the source/drain regions 130 in the vertical direction (Z direction). The frontside metal silicide film 172 may be in contact with the main epitaxial layer 136 of the corresponding one of the source/drain regions 130, and the frontside source/drain contact CA may be configured to be connected to the main epitaxial layer 136 of the corresponding one of the source/drain regions 130 through the frontside metal silicide film 172.

As shown in FIG. 3A, in the plurality of source/drain regions 130 included in the IC device 100, the source/drain region 130 (or the first source/drain region) connected to the backside via contact BCA may be different from the source/drain region 130 (or the second source/drain region) connected to the frontside source/drain contact CA. That is, the source/drain region 130 (or the first source/drain region) connected to the backside via contact BCA may be apart from the source/drain region 130 (or the second source/drain region) connected to the frontside source/drain contact CA. However, inventive concepts are not limited thereto. For example, the frontside source/drain contact CA and the backside via contact BCA may be configured to be connected to one common source/drain region 130.

As shown in FIG. 3A, the IC device 100 may include a plurality of backside bulk insulating films BBI and a plurality of backside power rails MPR. The plurality of backside bulk insulating films BBI may be arranged in a line in the first lateral direction (X direction) and each extend lengthwise in the second lateral direction (Y direction). The plurality of backside power rails MPR may be separated from each other by the plurality of backside bulk insulating films BBI in the first lateral direction (X direction). As shown in FIG. 3A, each of the plurality of backside power rails MPR may be between two adjacent ones of the plurality of backside bulk insulating films BBI in the first lateral direction (X direction). The backside via contact BCA may be integrally connected to a selected one of the plurality of backside power rails MPR.

In the IC device 100, the plurality of nanosheet stacks NSS may be apart from the plurality of backside bulk insulating films BBI in the vertical direction (Z direction). The blocking epitaxial layer 134 of each of the plurality of source/drain regions 130 may be in contact with the first to fourth nanosheets N1, N2, N3, and N4 included in the nanosheet stack NSS adjacent thereto, from among the plurality of nanosheet stacks NSS.

Each of the plurality of backside bulk insulating films BBI may be in contact with a pair of backside power rails MPR, which are adjacent to each other and selected from the plurality of backside power rails MPR. Each of the plurality of backside bulk insulating films BBI may extend lengthwise in the vertical direction (Z direction) from a space between the pair of backside power rails MPR, which are adjacent to each other, toward a selected one of the plurality of gate lines 160. In some example embodiments, each of the plurality of backside bulk insulating films BBI may include a nitrogen (N)-containing insulating film. For example, each of the plurality of backside bulk insulating films BBI may include one or more of a silicon nitride (SiN) film, a silicon carbonitride (SiCN) film, a silicon oxycarbonitride (SiOCN) film, without being limited thereto.

The backside via contact BCA may extend lengthwise in the vertical direction (Z direction) between a pair of backside bulk insulating films BBI adjacent to each other, from among the plurality of backside bulk insulating films BBI.

From among the plurality of backside power rails MPR, the pair of backside power rails MPR, which are integrally connected to the backside via contact BCA, may be apart from the source/drain region 130 in the vertical direction (Z direction) with the backside via contact BCA therebetween. As shown in FIG. 3C, the plurality of backside power rails MPR may extend lengthwise in the second lateral direction (Y direction).

In some example embodiments, the backside via contact BCA and the backside power rail MPR may be simultaneously formed using a single process such as a single deposition and may include the same material. In some example embodiments, the backside via contact BCA and the backside power rail MPR may be formed using separate processes, and there may be an interface between the backside via contact BCA and the backside power rail MPR. In some example embodiments, the backside via contact BCA and the backside power rail MPR may include a single metal. In some embodiments, the backside via contact BCA and the backside power rail MPR may include a metal plug and a conductive barrier film surrounding the metal plug. The metal plug may include one or more of molybdenum (Mo), tungsten (W), cobalt (Co), ruthenium (Ru), manganese (Mn), titanium (Ti), tantalum (Ta), aluminum (Al), copper (Cu), or an alloy thereof, without being limited thereto. The conductive barrier film may include a metal and/or a conductive metal nitride. For example, the conductive barrier film may include one or more of titanium (Ti), tantalum (Ta), tungsten (W), titanium nitride (TiN), tantalum nitride (TaN), tungsten nitride (WN), tungsten carbonitride (WCN), titanium silicon nitride (TiSiN), tantalum silicon nitride (TaSiN), tungsten silicon nitride (WSiN), without being limited thereto.

The plurality of backside bulk insulating films BBI may include a pair of backside bulk insulating films BBI, which are respectively on both sides of the backside via contact BCA and are apart from each other with the backside via contact BCA therebetween in the first lateral direction (X direction). Each of the pair of backside bulk insulating films BBI may overlap or at least partially overlap a selected one of the plurality of gate lines 160 in the vertical direction (Z direction) and extend lengthwise in the vertical direction (Z direction). The pair of backside bulk insulating films BBI may include portions facing the backside via contact BCA in the first lateral direction (X direction). Each of the plurality of backside bulk insulating films BBI may contact the gate dielectric film 152.

As shown in FIG. 3A, the IC device 100 may include a plurality of semiconductor blocks SB. From among the plurality of semiconductor blocks SB, some semiconductor blocks SB may cover sidewalls of the backside via contact BCA in the first lateral direction (X direction). From among the plurality of semiconductor blocks SB, some other semiconductor blocks SB may be in contact with a bottom surface of a back side of the bottom epitaxial layer 132 included in the source/drain region 130 connected to the frontside source/drain contact CA. Each of the plurality of semiconductor blocks SB may include silicon (Si).

From among the plurality of semiconductor blocks SB, at least some semiconductor blocks SB may cover sidewalls of the backside bulk insulating film BBI in the first lateral direction (X direction). The plurality of semiconductor blocks SB may contact the gate dielectric film 152 covering a lowermost surface of the gate line 160. As used herein, the lowermost surface of the gate line 160 may refer to a surface of the gate line 160, which is closest to the backside power rail MPR.

As shown in FIG. 3B, both sidewalls of a portion of the backside bulk insulating film BBI, which is adjacent to the gate line 160, in the second lateral direction (Y direction) may be covered by a device isolation film 112. As shown in FIG. 3C, both sidewalls of at least one of the plurality of semiconductor blocks SB in the second lateral direction (Y direction) may be covered by the device isolation film 112. At least one of the plurality of semiconductor blocks SB may have a surface contacting the source/drain region 130.

As shown in FIG. 3B, the device isolation film 112 may have a surface, which faces the gate line 160 with the gate dielectric film 152 therebetween, and a surface contacting the backside bulk insulating film BBI. As shown in FIG. 3C, the device isolation film 112 may include a surface, which faces the backside via contact BCA in the second lateral direction (Y direction) and contacts the backside via contact BCA, a surface contacting the backside power rail MPR, and a surface, which faces the semiconductor block SB in the second lateral direction (Y direction) and contacts the semiconductor block SB. The device isolation film 112 may include an oxide film and/or a nitride film.

As shown in FIGS. 3A and 3B, the plurality of backside bulk insulating films BBI may overlap or at least partially overlap the plurality of nanosheet stacks NSS in the vertical direction (Z direction). Each of the plurality of nanosheet stacks NSS may be apart from the backside bulk insulating film BBI in the vertical direction (Z direction). As used herein, the term “nanosheet” refers to a conductive structure having a cross-section that is substantially perpendicular to a direction in which current can flow. The nanosheet may be interpreted as including a nanowire. Some example embodiments pertain to an example in which one nanosheet stack NSS includes four nanosheets (e.g., the first to fourth nanosheets N1, N2, N3, and N4), but inventive concepts are not limited thereto. The number of nanosheets included in the nanosheet stack NSS may be variously selected as needed.

In one nanosheet stack NSS, the first to fourth nanosheets N1, N2, N3, and N4 may be apart from each other in the vertical direction (Z direction) and overlap each other in the vertical direction (Z direction). Each of the first to fourth nanosheets N1, N2, N3, and N4 included in one nanosheet stack NSS may be surrounded by one gate line 160. Each of the first to fourth nanosheets N1, N2, N3, and N4 included in one nanosheet stack NSS may be used as a channel region of the nanosheet transistor (refer to TR in FIG. 2). In some example embodiments, each of the first to fourth nanosheets N1, N2, N3, and N4 may independently or concurrently include a Si layer, a SiGe layer, or a combination thereof. In some example embodiments, the first to fourth nanosheets N1, N2, N3, and N4 may include the same material. In some example embodiments, the first to fourth nanosheets N1, N2, N3, and N4 may substantially have the same thickness in the vertical direction (Z direction).

As shown in FIGS. 3A and 3B, each of the plurality of gate lines 160 may surround the first to fourth nanosheets N1, N2, N3, and N4 while covering the plurality of nanosheet stacks NSS on the backside bulk insulating film BBI. Each of the plurality of gate lines 160 may include a main gate portion 160M and a plurality of sub-gate portions 160S. The main gate portion 160M may cover a top surface of the nanosheet stack NSS and extend lengthwise in the second lateral direction (Y direction). The plurality of sub-gate portions 160S may be integrally connected to the main gate portion 160M and fill respective spaces between the first to fourth nanosheets N1, N2, N3, and N4 and a space under a bottom surface of the first nanosheet N1. In the vertical direction (Z direction), a thickness of each of the plurality of sub-gate portions 160S may be less than a thickness of the main gate portion 160M. The plurality of gate lines 160 may extend to a space between the backside bulk insulating film BBI and the first nanosheet N1. Each of the first to fourth nanosheets N1, N2, N3, and N4 may have a gate-all-around (GAA) structure completely surrounding the gate line 160.

Each of the plurality of gate lines 160 may include a metal, a metal nitride, a metal carbide, or a combination thereof. The metal may be selected from one or more of titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from titanium nitride (TiN) and tantalum nitride (TaN). The metal carbide may include titanium aluminum carbide (TiAlC). However, a material included in the plurality of gate lines 160 is not limited to the examples described above.

A gate dielectric film 152 may be between the nanosheet stack NSS and the gate line 160. The gate dielectric film 152 may have a stack structure of an interface dielectric film and a high-k dielectric film. Electrical and/or physical properties of each gate dielectric film 152 may be the same around each nanosheet N1, N2, N3, N4; however example embodiments are not limited thereto. The interface dielectric film may include a low-k dielectric material film (e.g., a silicon oxide film, a silicon oxynitride film, or a combination thereof), which has a dielectric constant of about 9 or less. In some example embodiments, the interface dielectric film may be omitted. The high-k dielectric film may include a material having a higher dielectric constant than a silicon oxide film. For example, the high-k dielectric film may have a dielectric constant of about 10 to 25. The high-k dielectric film may include hafnium oxide, without being limited thereto.

Both sidewalls of each of the plurality of sub-gate portions 160S included in the plurality of gate lines 160 may be apart from the source/drain region 130 with the gate dielectric film 152 therebetween. The gate dielectric film 152 may include respective portions between the sub-gate portions 160S included in the gate line 160 and the first to fourth nanosheets N1, N2, N3, and N4, respective portions between the sub-gate portions 160S included in the gate line 160 and the source/drain region 130, and a portion between the backside bulk insulating film BBI and the sub-gate portion 160S, which is closest to the backside bulk insulating film BBI, from among the plurality of sub-gate portions 160S included in the gate line 160. The backside bulk insulating film BBI may include portions contacting the gate dielectric film 152.

In some example embodiments, at least one of the frontside source/drain contact CA and the backside via contact BCA may include only a metal plug including a single metal. In some example embodiments, at least one of the frontside source/drain contact CA and the backside via contact BCA may include a metal plug and a conductive barrier film surrounding the metal plug The metal plug may include one or more of molybdenum (Mo), tungsten (W), cobalt (Co), ruthenium (Ru), manganese (Mn), titanium (Ti), tantalum (Ta), aluminum (Al), copper (Cu), or an alloy thereof, without being limited thereto. The conductive barrier film may include a metal or a conductive metal nitride. For example, the conductive barrier film may include Ti, Ta, W, TIN, TaN, WN, WCN, TiSiN, TaSiN, WSiN, or a combination thereof, without being limited thereto.

In some example embodiments, each of the frontside metal silicide film 172 and the backside metal silicide film 198 may include the same and/or different components, such as one or more of Ti, W, Ru, Nb, Mo, Hf, Ni, Co, Pt, Yb, Tb, Dy, Er, or Pd. For example, each of the frontside metal silicide film 172 and the backside metal silicide film 198 may include titanium silicide.

As shown in FIG. 3A, both sidewalls of the gate line 160 may be covered by a plurality of main insulating spacers 118. Each of the plurality of main insulating spacers 118 may cover sidewalls of the main gate portion 160M on the top surface of the nanosheet stack NSS. Each of the plurality of main insulating spacers 118 may be apart from the gate line 160 with the gate dielectric film 152 therebetween.

As shown in FIG. 3C, a plurality of side insulating spacers 119 may be on the device isolation film 112. At least some of the plurality of side insulating spacers 119 may cover sidewalls of the source/drain region 130. In some example embodiments, each of the plurality of side insulating spacers 119 may be integrally connected to the main insulating spacer 118 adjacent thereto.

Each of the plurality of main insulating spacers 118 and the plurality of side insulating spacers 119 may include silicon nitride, silicon oxide, silicon oxycarbide (SiOC), silicon oxycarbonitride (SiOCN), silicon carbonitride (SiCN), silicon boron nitride (SiBN), silicon oxynitride (SiON), silicon boron carbonitride (SiBCN), SiOF, SiOCH, or a combination thereof. Each of the plurality of main insulating spacers 118 and the plurality of side insulating spacers 119 may include a single film including one or more material film selected from the materials described above or a multilayered film including a plurality of material films selected from the materials described above.

As shown in FIGS. 3A and 3B, a top surface of each of the gate line 160, the gate dielectric film 152, and the main insulating spacer 118 may be covered by a capping insulating pattern 168. The capping insulating pattern 168 may include a silicon nitride film.

The plurality of source/drain regions 130, the device isolation film 112, a plurality of main insulating spacers 118, and the plurality of side insulating spacers 119 may be covered by an insulating liner 142. An inter-gate dielectric film 144 may be on the insulating liner 142. The inter-gate dielectric film 144 may be between a pair of gate lines 160, which are adjacent to each other in the first lateral direction (X direction), and a pair of source/drain regions 130, which are adjacent to each other. In some example embodiments, the insulating liner 142 may include silicon nitride, SiCN, SiBN, SION, SIOCN, SiBCN, or a combination thereof, without being limited thereto. The inter-gate dielectric film 144 may include a silicon oxide film, without being limited thereto.

As shown in FIG. 3A, the frontside source/drain contact CA may be on the source/drain region 130 between a pair of gate lines 160, which are adjacent to each other, from among the plurality of gate lines 160. One frontside source/drain contact CA may be connected two adjacent ones of the source/drain regions 130 as shown in FIG. 2 or be connected to one source/drain region 130 unlike in FIG. 2, without being limited thereto. The frontside source/drain contact CA may be apart from the main gate portion 160M of the gate line 160 adjacent thereto in the first lateral direction (X direction) with the main insulating spacer 118 therebetween. A frontside insulating structure including the insulating liner 142 and the inter-gate dielectric film 144 may surround a sidewall of the frontside source/drain contact CA.

A top surface of each of the frontside source/drain contact CA, a plurality of capping insulating patterns 168, the insulating liner 142, and the inter-gate dielectric film 144 may be covered by an upper insulating structure 180. The upper insulating structure 180 may include an etch stop film 182 and an upper insulating film 184. The etch stop film 182 may include silicon carbide (SiC), silicon nitride (SiN), silicon carbonitride (SiCN), silicon oxycarbide (SiOC), aluminum nitride (AlN), aluminum oxynitride (AlON), aluminum oxide (AIO), aluminum oxycarbide (AlOC), or a combination thereof. The upper insulating film 184 may include an oxide film, a nitride film, an ultralow-k (ULK) film having an ultralow dielectric constant K of about 2.2 to about 2.4, or a combination thereof. For example, the upper insulating film 184 may include a tetraethylorthosilicate (TEOS) film, a high-density plasma (HDP) film, a boro-phospho-silicate glass (BPSG) film, a flowable chemical vapor deposition (FCVD) oxide film, a silicon oxynitride (SiON) film, a silicon nitride (SiN) film, a silicon oxycarbide (SiOC) film, a SiCOH film, or a combination thereof, without being limited thereto.

A source/drain via contact VA may be on the frontside source/drain contact CA. Each of a plurality of source/drain via contacts VA may pass through the upper insulating structure 180 and contact the frontside source/drain contact CA. From among the plurality of source/drain regions 130, the source/drain region 130 connected to the frontside source/drain contact CA may be configured to be electrically connected to the source/drain via contact VA through the frontside metal silicide film 172 and the frontside source/drain contact CA. Each of the plurality of source/drain via contacts VA may include molybdenum (Mo) or tungsten (W), without being limited thereto.

As shown in FIG. 3B, a gate contact CB may be on the gate line 160. The gate contact CB may be configured to pass through the upper insulating structure 180 and the capping insulating pattern 168 in the vertical direction (Z direction) and be connected to the gate line 160. A bottom surface of the gate contact CB may be in contact with the top surface of the gate line 160. The gate contact CB may include a contact plug, which includes molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but a constituent material of the contact plug is not limited thereto. In some example embodiments, the gate contact CB may further include a conductive barrier pattern surrounding a portion of the contact plug. The conductive barrier pattern included in the gate contact CB may include a metal or a metal nitride. For example, the conductive barrier pattern may include Ti, Ta, W, TiN, TaN, WN, WCN, TiSiN, TaSiN, WSiN, or a combination thereof, without being limited thereto.

A top surface of the upper insulating structure 180 may be covered by a frontside interlayer insulating film 186. A constituent material of the frontside interlayer insulating film 186 may substantially be the same as that of the upper insulating film 184, which has been described above. A plurality of upper wiring layers M1 may pass through the frontside interlayer insulating film 186. The plurality of upper wiring layers M1 may be connected to the source/drain via contact VA or the gate contact CB. The plurality of upper wiring layers M1 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, without being limited thereto.

As described above with reference to FIGS. 2 and 3A to 3E, in the IC device 100, each of the plurality of source/drain regions 130 included in the plurality of nanosheet transistors TR may include a bottom epitaxial layer 132 that has a shape protruding from the bottom surface of the back side of the corresponding one of the source/drain regions 130 toward the central portion thereof in the vertical direction (Z direction), and the bottom epitaxial layer 132 may have a highest dopant concentration in the corresponding one of the source/drain regions 130. The backside via contact BCA and the backside metal silicide film 198 may pass through a portion of the bottom epitaxial layer 132 of the corresponding one of the source/drain regions 130 in the vertical direction (Z direction) and be connected to the corresponding one of the source/drain regions 130, and the backside metal silicide film 198 may be in contact with the bottom epitaxial layer 132 of the corresponding one of the source/drain regions 130. Thus, the backside via contact BCA may be configured to be connected to the corresponding one of the source/drain regions 130 through the backside metal silicide film 198. As described above, the backside metal silicide film 198 located between the backside via contact BCA and the source/drain region 130 may have a structure that contacts the bottom epitaxial layer 132, which has a highest dopant concentration in the source/drain region 130. As a result, a Schottky barrier height between the backside via contact BCA and the source/drain region 130 may be reduced, and thus, resistance between the backside via contact BCA and the source/drain region 130 may be reduced. Therefore, the electrical reliability of the IC device 100 may be improved by suppressing or reducing an increase in contact resistance, e.g., non-ohmic contact resistance, between the backside via contact BCA and the source/drain region 130.

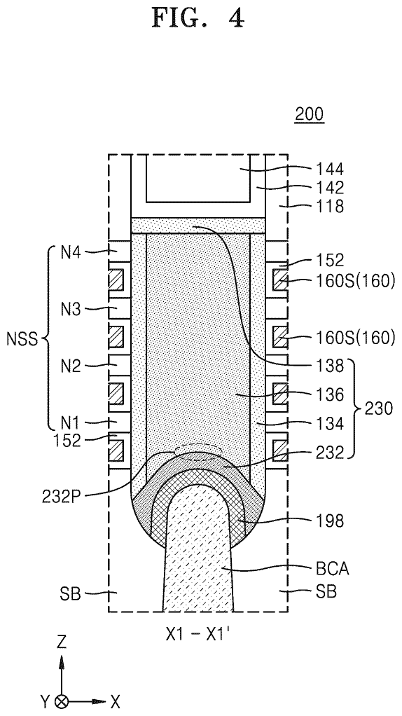

FIGS. 4 to 9 are respectively cross-sectional views of IC devices 200, 300, 400, 500, 600, and 700 according to some example embodiments. FIGS. 4 to 9 respectively illustrate enlarged cross-sectional configurations of portions corresponding to portion “EX1” of FIG. 3A in the IC devices 200, 300, 400, 500, 600, and 700. In FIGS. 4 to 9, the same reference numerals are used to denote the same elements as in FIGS. 2 and 3A to 3E, and detailed descriptions thereof are omitted. Components shown in each of FIGS. 4 to 9 may constitute some of the plurality of cells LC shown in FIG. 1.

Referring to FIG. 4, the IC device 200 may substantially have the same configuration as the IC device 100 described with reference to FIGS. 2 and 3A to 3E. However, the IC device 200 may include a source/drain region 230.

The source/drain region 230 may substantially have the same configuration as the source/drain region 130 described with reference to FIGS. 3A, 3C, 3D, and 3E. However, the source/drain region 230 may include a bottom epitaxial layer 232, a blocking epitaxial layer 134, a main epitaxial layer 136, and a capping layer 138. Detailed configurations of the blocking epitaxial layer 134, the main epitaxial layer 136, and the capping layer 138 may be the same as those described with reference to FIGS. 3A, 3C, 3D, and 3E. In some example embodiments, the capping layer 138 may be omitted in the source/drain region 230.

The bottom epitaxial layer 232 may substantially have the same configuration as the bottom epitaxial layer 132 described with reference to FIGS. 3A, 3C, 3D, and 3E. However, the bottom epitaxial layer 232 may have an upper surface having a convex (e.g., rounded or curved) shape, which gets close to a top surface of a front side of the source/drain region 230 toward a central portion of the source/drain region 230 in a first lateral direction (X direction), and the top surface of the bottom epitaxial layer 232 may include a ridge portion 232P with a curved surface. The top surface of the bottom epitaxial layer 232 may not include a facet having a specific plane orientation. For example, the top surface of the bottom epitaxial layer 232 may include a facet having a {111} plane orientation or a {100} plane orientation. A constituent material of the bottom epitaxial layer 232 may be the same as that of the bottom epitaxial layer 132, which has been described with reference to FIGS. 3A, 3C, 3D, and 3E.

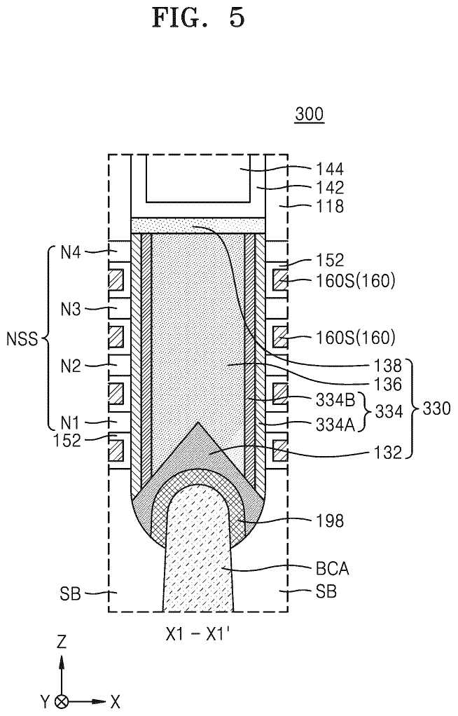

Referring to FIG. 5, the IC device 300 may substantially have the same configuration as the IC device 100 described with reference to FIGS. 2 and 3A to 3E. However, the IC device 300 may include a source/drain region 330.

The source/drain region 330 may substantially have the same configuration as the source/drain region 130 described with reference to FIGS. 3A, 3C, 3D, and 3E. However, the source/drain region 330 may include a bottom epitaxial layer 132, a blocking epitaxial layer 334, a main epitaxial layer 136, and a capping layer 138. Detailed configurations of the bottom epitaxial layer 132, the main epitaxial layer 136, and the capping layer 138 may be the same as those of described with reference to FIGS. 3A, 3C, 3D, and 3E. In some example embodiments, the capping layer 138 may be omitted in the source/drain region 330.

The blocking epitaxial layer 334 may substantially have the same configuration as the blocking epitaxial layer 134 described with reference to FIGS. 3A, 3C, 3D, and 3E. However, the blocking epitaxial layer 334 may have a multilayered structure. More specifically, the blocking epitaxial layer 334 may include a first blocking epitaxial layer 334A and a second blocking epitaxial layer 334B, which are sequentially stacked on sidewalls of each of the first to fourth nanosheets N1, N2, N3, and N4 included in the nanosheet stack NSS.

The first blocking epitaxial layer 334A may have surfaces contacting the first to fourth nanosheets N1, N2, N3, and N4 included in the nanosheet stack NSS, a surface contacting the second blocking epitaxial layer 334B, and a surface contacting the bottom epitaxial layer 132. The second blocking epitaxial layer 334B may be apart from the first to fourth nanosheets N1, N2, N3, and N4 in the first lateral direction (X direction) with the first blocking epitaxial layer 334A therebetween. The second blocking epitaxial layer 334B may have a surface contacting the first blocking epitaxial layer 334A, a surface contacting the main epitaxial layer 136, and a surface contacting the bottom epitaxial layer 132. In each of the first blocking epitaxial layer 334A and the second blocking epitaxial layer 334B, a surface facing the main epitaxial layer 136 may include a facet having a {110} plane orientation.

The first blocking epitaxial layer 334A and the second blocking epitaxial layer 334B may include the same semiconductor material, and respective dopants included in the first blocking epitaxial layer 334A and the second blocking epitaxial layer 334B may be different from each other.

In some example embodiments, the source/drain region 330 of the IC device 300 may constitute or correspond to an NMOS transistor, and the source/drain region 330 may include a Si layer doped with an n-type dopant. In the source/drain region 330, a concentration of an n-type dopant in the bottom epitaxial layer 132 may be greater than a concentration of an n-type dopant in each of the blocking epitaxial layer 334 and the capping layer 138 and be greater than or equal to a concentration of an n-type dopant in the main epitaxial layer 136.

In some example embodiments, the n-type dopant included in each of the bottom epitaxial layer 132, the main epitaxial layer 136, and the capping layer 138 may be phosphorus (P). In the blocking epitaxial layer 334, an n-type dopant included in the first blocking epitaxial layer 334A in contact with the first to fourth nanosheets N1, N2, N3, and N4 may be arsenic (As), and an n-type dopant included in the second blocking epitaxial layer 334B in contact with the main epitaxial layer 136 may be phosphorus (P). In this case, in each of a plurality of source/drain regions 130, a dopant concentration of phosphorus in the bottom epitaxial layer 132 may be in a range of about 8×10²⁰ atoms/cm³ to about 6×10²¹ atoms/cm³, and a dopant concentration of arsenic in the first blocking epitaxial layer 334A may be in a range of about 1×10¹⁸ atoms/cm³ to about 1×10¹⁹ atoms/cm³. A dopant concentration of phosphorus in the second blocking epitaxial layer 334B may be in a range of about 1×10¹⁸ atoms/cm³ to about 1×10¹⁹ atoms/cm³, and a dopant concentration of phosphorus in the main epitaxial layer 136 may be in a range of about 1×10²¹ atoms/cm³ to about 4×10²¹ atoms/cm³, and a dopant concentration of phosphorus in the capping layer 138 may be in a range of about 1×10¹⁹ to about 5×10²⁰ atoms/cm³.

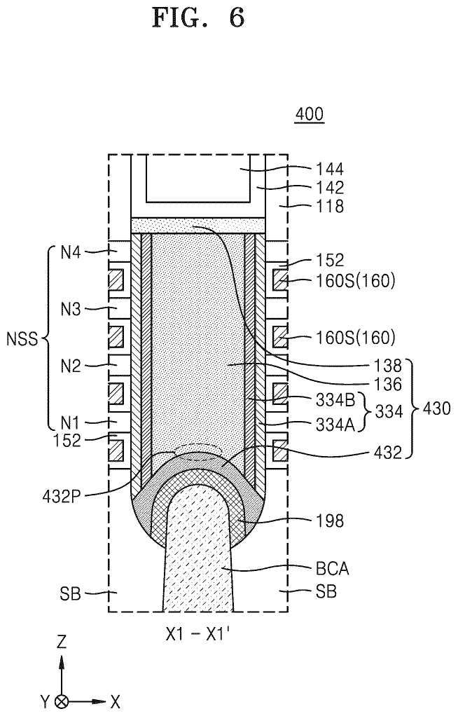

Referring to FIG. 6, the IC device 400 may substantially have the same configuration as the IC device 300 described with reference to FIG. 5. However, the IC device 300 may include a source/drain region 430.

The source/drain region 430 may substantially have the same configuration as the source/drain region 330 described with reference to FIG. 5. However, the source/drain region 430 may include a bottom epitaxial layer 432, a blocking epitaxial layer 334, a main epitaxial layer 136, and a capping layer 138. Detailed configurations of the blocking epitaxial layer 334, the main epitaxial layer 136, and the capping layer 138 may be the same as those described with reference to FIGS. 3A, 3C, 3D, and 3E. In some example embodiments, the capping layer 138 may be omitted from the source/drain region 430.

The bottom epitaxial layer 432 may substantially have the same configuration as the bottom epitaxial layer 132 described with reference to FIGS. 3A, 3C, 3D, and 3E. However, the bottom epitaxial layer 432 may include an upper surface having a convex shape, which gets close to a top surface of a front side of the source/drain region 430 toward a central portion of the source/drain region 430 in the first lateral direction (X direction), and the top surface of the bottom epitaxial layer 432 may include a ridge portion 432P with a curved surface. The top surface of the bottom epitaxial layer 432 may not include a facet having a specific plane orientation. For example, the top surface of the bottom epitaxial layer 432 may not include a facet having a {111} plane orientation or a {100} plane orientation. A constituent material of the bottom epitaxial layer 432 may be the same as that of the bottom epitaxial layer 132, which has been described with reference to FIGS. 3A, 3C, 3D, and 3E.

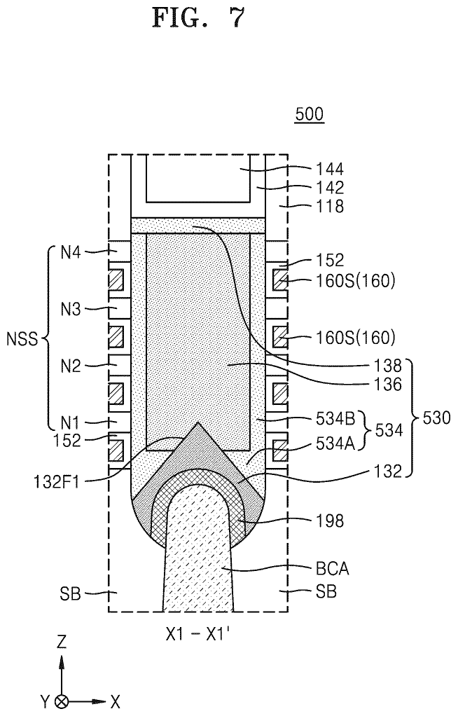

Referring to FIG. 7, the IC device 500 may substantially have the same configuration as the IC device 100 described with reference to FIGS. 2 and 3A to 3E. However, the IC device 500 may include a source/drain region 530.

The source/drain region 530 may substantially have the same configuration as the source/drain region 130 described with reference to FIGS. 3A, 3C, 3D, and 3E. However, the source/drain region 530 may include a bottom epitaxial layer 132, a blocking epitaxial layer 534, a main epitaxial layer 136, and a capping layer 138. Detailed configurations of the bottom epitaxial layer 132, the main epitaxial layer 136, and the capping layer 138 may be the same as those described with reference to FIGS. 3A, 3C, 3D, and 3E. In some example embodiments, the capping layer 138 may be omitted in the source/drain region 530.

In the source/drain region 530, the blocking epitaxial layer 534 may substantially have the same configuration as the blocking epitaxial layer 134 described with reference to FIGS. 3A, 3C, 3D, and 3E. However, a width of the blocking epitaxial layer 534 in the first lateral direction (X direction) may not be constant in a vertical direction (Z direction). The blocking epitaxial layer 534 may include a variable width portion 534A contacting the bottom epitaxial layer 132 and a constant width portion 534B integrally connected to the variable width portion 534A. The constant width portion 534B may extend upward from the variable width portion 534A toward the capping layer 138. The blocking epitaxial layer 534 may have a greatest width in the first lateral direction (X direction) at the variable width portion 534A, which contacts the bottom epitaxial layer 132.

In the source/drain region 530, the variable width portion 534A of the blocking epitaxial layer 534 may be in contact with a portion of the first facet 132F1 of the bottom epitaxial layer 132. Another portion of the first facet 132F1 of the bottom epitaxial layer 132, which is not in contact with the variable width portion 534A of the blocking epitaxial layer 534, may be in contact with the main epitaxial layer 136.

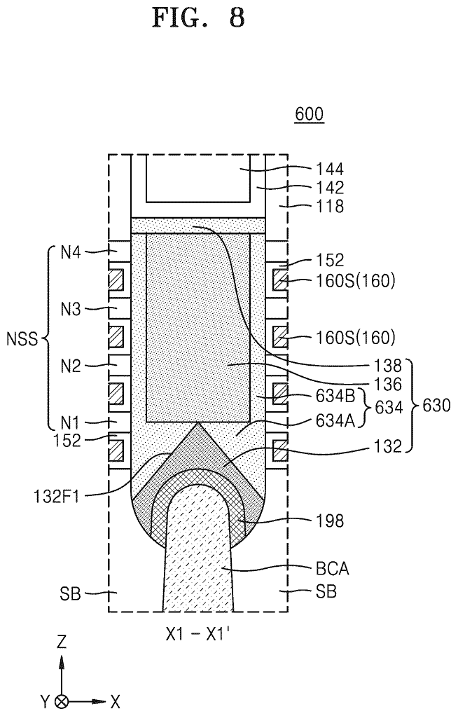

Referring to FIG. 8, the IC device 600 may substantially have the same configuration as the IC device 100 described with reference to FIGS. 2 and 3A to 3E. However, the IC device 600 may include a source/drain region 630.

The source/drain region 630 may substantially have the same configuration as the source/drain region 130 described with reference to FIGS. 3A, 3C, 3D, and 3E. However, the source/drain region 630 may include a bottom epitaxial layer 132, a blocking epitaxial layer 634, a main epitaxial layer 136, and a capping layer 138. Detailed configurations of the bottom epitaxial layer 132, the main epitaxial layer 136, and the capping layer 138 are the same as those described with reference to FIGS. 3A, 3C, 3D, and 3E. In some example embodiments, the capping layer 138 may be omitted in the source/drain region 630.

The blocking epitaxial layer 634 may substantially have the same configuration as the blocking epitaxial layer 134 described with reference to FIGS. 3A, 3C, 3D, and 3E. However, a width of the blocking epitaxial layer 634 in the first lateral direction (X direction) may not be constant in the vertical direction (Z direction). The blocking epitaxial layer 634 may include a variable width portion 634A contacting the bottom epitaxial layer 132 and a constant width portion 634B integrally connected to the variable width portion 634A. The constant width portion 634B may extend upward from the variable width portion 634A toward the capping layer 138. In the source/drain region 630, the blocking epitaxial layer 634 may have a greatest width in the first lateral direction (X direction) at the variable width portion 634A, which contacts the bottom epitaxial layer 132.

In the source/drain region 630, the variable width portion 634A of the blocking epitaxial layer 634 may contact the first facet 132F1 of the bottom epitaxial layer 132. The first facet 132F1 of the bottom epitaxial layer 132 may contact only the variable width portion 634A of the blocking epitaxial layer 634 without contacting the main epitaxial layer 136. In some example embodiments, the bottom epitaxial layer 132 may be apart from the main epitaxial layer 136 with the variable width portion 634A of the blocking epitaxial layer 634 therebetween. The main epitaxial layer 136 may be in contact with only the blocking epitaxial layer 634, from among the bottom epitaxial layer 132 and the blocking epitaxial layer 634.

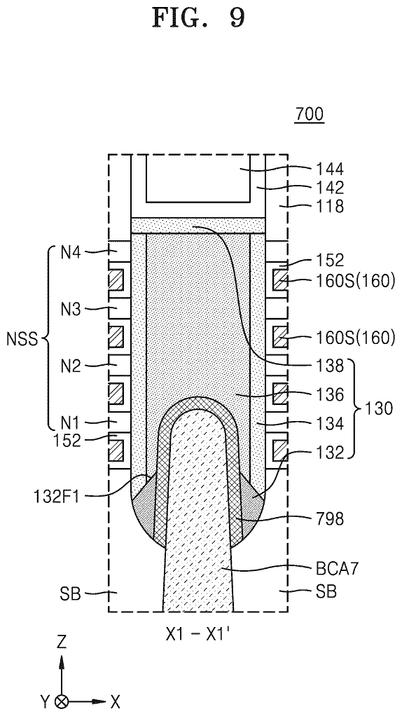

Referring to FIG. 9, the IC device 700 may substantially have the same configuration as the IC device 100 described with reference to FIGS. 2 and 3A to 3E. However, the IC device 700 may include a backside via contact BCA7 and a backside metal silicide film 798. The backside via contact BCA7 may pass through a lower portion of the source/drain region 130 in the vertical direction (Z direction) from a back side of the source/drain region 130. The backside metal silicide film 798 may be between the source/drain region 130 and the backside via contact BCA7. The backside via contact BCA7 may be configured to be connected to the source/drain region 130 through the backside metal silicide film 798.

The backside via contact BCA7 and the backside metal silicide film 798 may respectively and substantially have the same configurations as the backside via contact BCA and the backside metal silicide film 198 described with reference to FIGS. 3A, 3C, 3D, and 3E. However, the backside via contact BCA7 may extend lengthwise in the vertical direction (Z direction) such that the backside via contact BCA7 completely passes through the bottom epitaxial layer 132 in the vertical direction (Z direction) and passes through a portion of the main epitaxial layer 136 in the vertical direction (Z direction). The backside metal silicide film 798 may be in contact with each of the bottom epitaxial layer 132 and the main epitaxial layer 136.

Example embodiments are not limited to the above. For example, some example embodiments may include one or more features described with reference to one or more of FIGS. 5-9, and may also include one or more features described with reference to others of FIGS. 5-9.

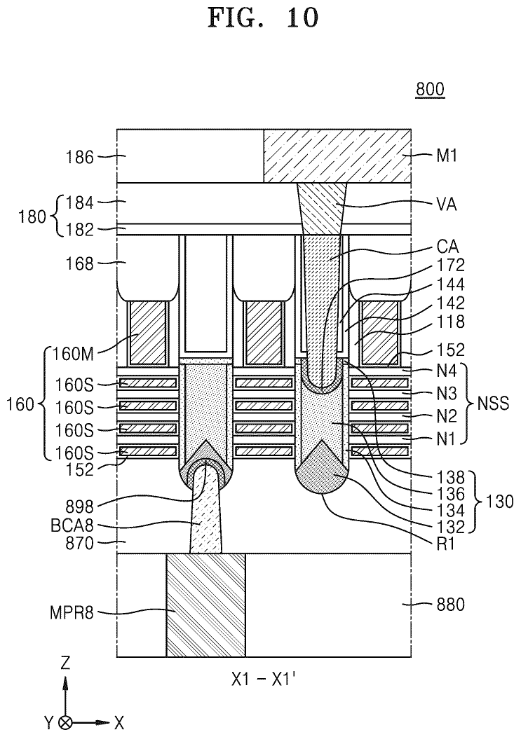

FIG. 10 is a cross-sectional view of an IC device 800 according to some example embodiments. FIG. 10 illustrates a cross-sectional configuration of a portion corresponding to a cross-section taken along line X1-X1′ of FIG. 2, in the IC device 800. In FIG. 10, the same reference numerals are used to denote the same elements as in FIGS. 2 and 3A to 3E, and detailed descriptions thereof are omitted. Components shown in FIG. 10 may constitute or be included in some of the plurality of cells LC shown in FIG. 1.

Referring to FIG. 10, the IC device 800 may substantially have the same configuration as the IC device 100 described with reference to FIGS. 2 and 3A to 3E. However, the IC device 800 may include a first backside insulating film 870, a backside via contact BCA8, and a backside metal silicide film 898. The first backside insulating film 870 may contact each of a plurality of source/drain regions 130 and a plurality of gate dielectric films 152. The backside via contact BCA8 may pass through the first backside insulating film 870 in a vertical direction (Z direction) and be connected to the corresponding one of the source/drain regions 130. The backside metal silicide film 898 may be between the source/drain region 130 and the backside via contact BCA8. The backside via contact BCA8 may pass through a lower portion of the source/drain region 130 from a back side of the source/drain region 130 in the vertical direction (Z direction). The backside via contact BCA8 may be configured to be connected to the source/drain region 130 through the backside metal silicide film 898.

The backside via contact BCA8 and the backside metal silicide film 898 may respectively and substantially have the same configurations as the backside via contact BCA and the backside metal silicide film 198 described with reference to FIGS. 3A, 3C, 3D, and 3E. However, of the backside via contact BCA8, a lower end opposite to an upper end that contacts the backside metal silicide film 898 may contact the backside power rail MPR8. The backside via contact BCA8 and the backside power rail MPR8 may be formed using different processes, and there may be an interface between the backside via contact BCA8 and the backside power rail MPR8. The backside power rail MPR8 may pass through the second backside insulating film 880 in the vertical direction (Z direction).

Constituent materials of the backside via contact BCA8 and the backside power rail MPR8 may substantially be the same as those of the backside via contact BCA and the backside power rail MPR, which have been described with reference to FIGS. 3A, 3C, 3D, and 3E. In some example embodiments, the backside via contact BCA8 and the backside power rail MPR8 may include the same material as each other. In some example embodiments, the backside via contact BCA8 and the backside power rail MPR8 may include different materials from each other.

In some example embodiments, each of the first backside insulating film 870 and the second backside insulating film 880 may include a silicon oxide film, a silicon nitride film, a silicon carbide film, a low-k dielectric film, an ultralow-k (ULK) film having an ultralow dielectric constant K of about 2.2 to about 2.4, or a combination thereof. The low-k dielectric film may include fluorine-doped silicon oxide, organosilicate glass, carbon-doped oxide, porous silicon oxide, porous organosilicate glass, a spin-on organic polymeric dielectric, a spin-on silicon-based polymeric dielectric, or a combination thereof, without being limited thereto. For example, each of the first backside insulating film 870 and the second backside insulating film 880 may include a tetraethylorthosilicate (TEOS) film, a high-density plasma (HDP) film, a boro-phospho-silicate glass (BPSG) film, a flowable chemical vapor deposition (FCVD) oxide film, a silicon oxynitride (SiON) film, a silicon nitride (SiN) film, a silicon oxycarbide (SiOC) film, a SiCOH film, or a combination thereof, without being limited thereto.

Like the IC device 100 described with reference to FIGS. 2, 3A to 3C, and 4, in the IC devices 200, 300, 400, 500, 600, 700, and 800 described with reference to FIGS. 4 to 10, the source/drain regions 130, 230, 330, 430, 530, and 630 may include the bottom epitaxial layers 132, 232, and 432, each of which has a shape protruding from the bottom surface of the back side of the corresponding one of the source/drain regions 130, 230, 330, 430, 530, and 630 toward the central portion thereof in the vertical direction (Z direction). Each of the bottom epitaxial layers 132, 232, and 432 may have a highest dopant concentration in the corresponding one of the source/drain regions 130, 230, 330, 430, 530, and 630. The backside via contacts BCA, BCA7, and BCA8 and the backside metal silicide films 198, 798, 898 may pass through at least portions of the bottom epitaxial layers 132, 232, and 432 of the corresponding ones of the source/drain regions 130, 230, 330, 430, 530, and 630 in the vertical direction (Z direction) and be connected to the corresponding ones of the source/drain regions 130, 230, 330, 430, 530, and 630, and the backside metal silicide films 198, 798, and 898 may contact the bottom epitaxial layers 132, 232, and 432 of the corresponding ones of the source/drain regions 130, 230, 330, 430, 530, and 630. Thus, the backside via contacts BCA, BCA7, and BCA8 may be configured to be connected to the corresponding ones of the source/drain regions 130, 230, 330, 430, 530, and 630 through the backside metal silicide films 198, 798, and 898. As described above, the backside metal silicide films 198, 798, and 898 located between the backside via contacts BCA, BCA7, and BCA8 and the source/drain regions 130, 230, 330, 430, 530, and 630 may have structures that contact the bottom epitaxial layers 132, 232, and 432, which have highest dopant concentrations in the source/drain regions 130, 230, 330, 430, 530, and 630. As a result, Schottky barrier heights between the backside via contacts BCA, BCA7, and BCA8 and the source/drain regions 130, 230, 330, 430, 530, and 630 may be reduced, and thus, resistances between the backside via contacts BCA, BCA7, and BCA8 and the source/drain regions 130, 230, 330, 430, 530, and 630 may be reduced. Therefore, the electrical reliability of the IC devices 200, 300, 400, 500, 600, 700, and 800 may be improved by suppressing or reducing increases in contact resistances between the backside via contacts BCA, BCA7, and BCA8 and the source/drain regions 130, 230, 330, 430, 530, and 630.

Next, a method of manufacturing or fabricating an IC device, according to some example embodiments, is described in detail.

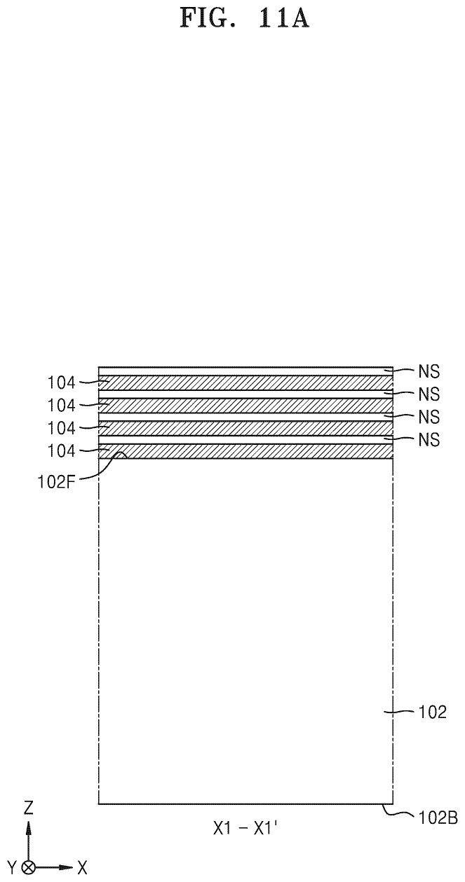

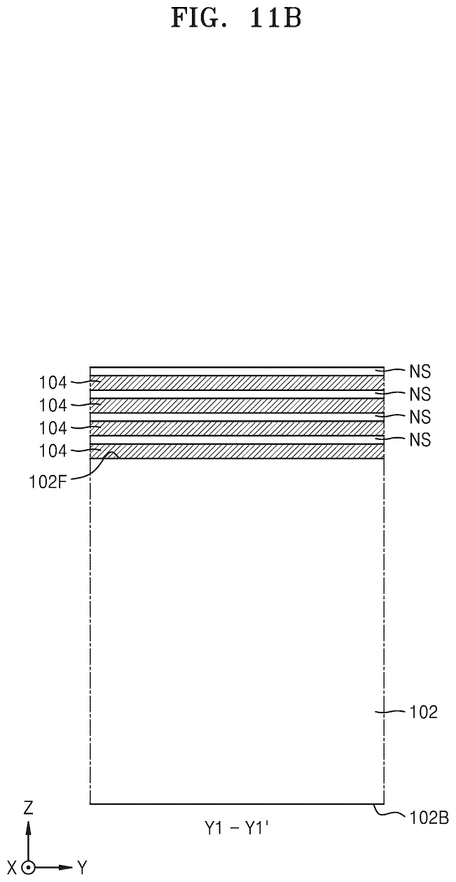

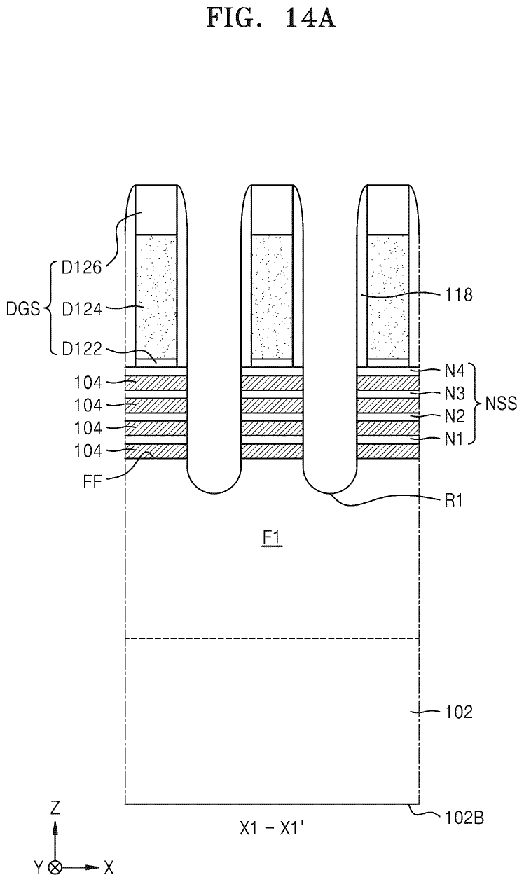

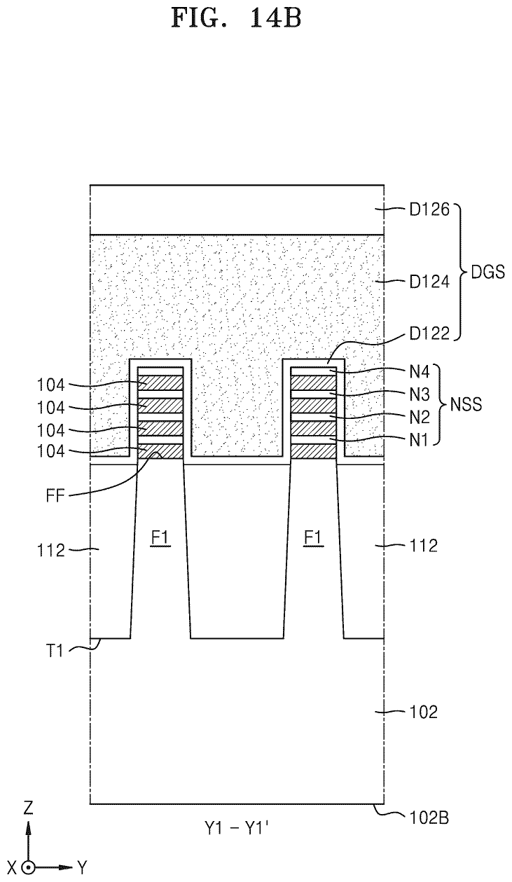

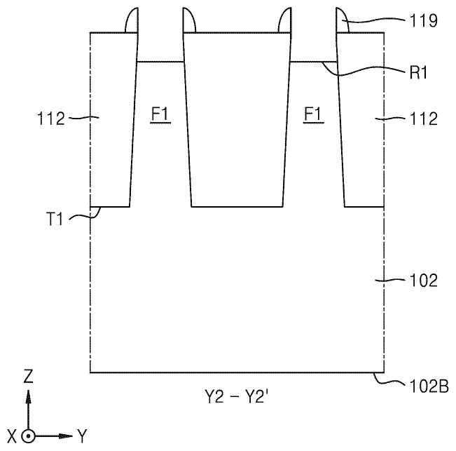

FIGS. 11A to 29B are cross-sectional views of a process sequence of a method of manufacturing an IC device, according to some example embodiments. More specifically, FIGS. 11A, 12A, 13A, 14A, 15A, 16, 17A, 18A, 19A, 20A, 21A, 22A, 23A, 24A, 25A, 26, 27A, 28A, and 29A are cross-sectional views of example cross-sectional structures of a portion corresponding to a cross-section taken along line X1-X1′ of FIG. 2, according to the process sequence. FIGS. 11B, 12B, 13B, 14B, 18B, 19B, 20B, 21B, 22B, 23B, 24B, and 25B are cross-sectional views of example cross-sectional structures of a portion corresponding to a cross-section taken along line Y1-Y1′ of FIG. 2, according to the process sequence. FIGS. 14C, 15B, 17B, 18C, 22C, 23C, 24B, 27B, 28B, and 29B are cross-sectional views of example cross-sectional structures of a portion corresponding to a cross-section taken along line Y2-Y2′ of FIG. 2, according to the process sequence.

An example of a method of manufacturing the IC device 100 described with reference to FIGS. 2 and 3A to 3E is described with reference to FIGS. 11A to 29B. In FIGS. 11A to 29B, the same reference numerals are used to denote the same elements as in FIGS. 2 and 3A to 3E, and detailed descriptions thereof are omitted.

Referring to FIGS. 11A and 11B, a substrate 102 having a frontside surface 102F and a backside surface 102B, which are opposite to each other, may be prepared. A plurality of sacrificial semiconductor layers 104 and a plurality of nanosheet semiconductor layers NS may be alternately stacked one-by-one on the frontside surface 102F of the substrate 102 to form a stack structure, e.g., with a process such as an atomic layer deposition (ALD) process.

In the stack structure, the plurality of sacrificial semiconductor layers 104 and the plurality of nanosheet semiconductor layers NS may include semiconductor materials having different etch selectivities (e.g., wet or isotropic etch rates) from each other. In some example embodiments, the plurality of nanosheet semiconductor layers NS may include a Si film and in some cases may not include a SiGe film, and the plurality of sacrificial semiconductor layers 104 may include a SiGe film and in some cases may not include an Si film. The SiGe film included in the sacrificial semiconductor layer 104 may have a constant Ge content, which is selected in a range of about 5 at % to about 50 at %, for example, about 10 at % to about 40 at %. In some example embodiments, the plurality of sacrificial semiconductor layers 104 may each include a SiGe film and have the same Ge content.

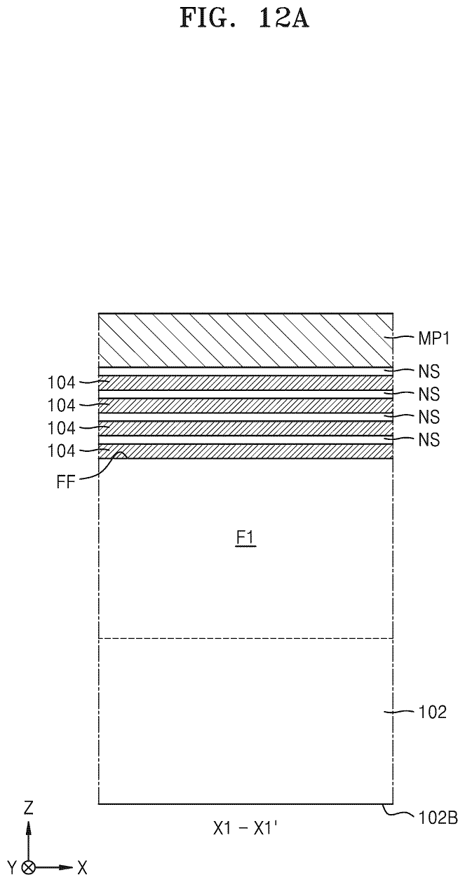

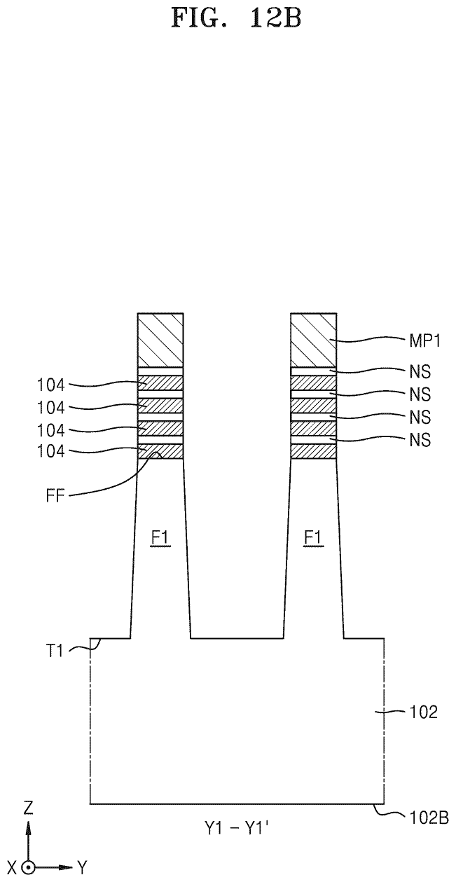

Referring to FIGS. 12A and 12B, a mask pattern MP1 having openings exposing a top surface of the stack structure may be formed on the resultant structure of FIGS. 11A and 11B. The mask pattern MP1 may have a stack structure of a silicon oxide film pattern and a silicon nitride film pattern. The mask pattern MP1 may include portions extending parallel to each other in a first lateral direction (X direction) on the substrate 102. The mask pattern MP1 may be or include a soft-mask such as a photoresist layer, and/or a hard-mask such as a silicon nitride layer; example embodiments are not limited thereto.

A portion of each of the plurality of sacrificial semiconductor layers 104, the plurality of nanosheet semiconductor layers NS, and the substrate 102 may be etched, e.g., anisotropically etched, using the mask pattern MP1 as an etch mask, and thus, a plurality of fin-type active regions F1 may be formed on the substrate 102. A plurality of trench regions TI may be defined by the plurality of fin-type active regions F1 on the substrate 102. A portion of each of the plurality of sacrificial semiconductor layers 104 and the plurality of nanosheet semiconductor layers NS may remain on a fin top surface FF of each of the plurality of fin-type active regions F1.

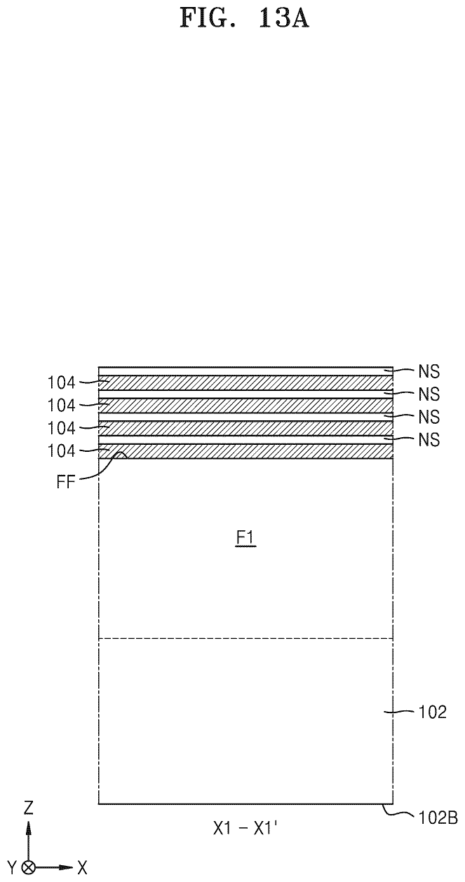

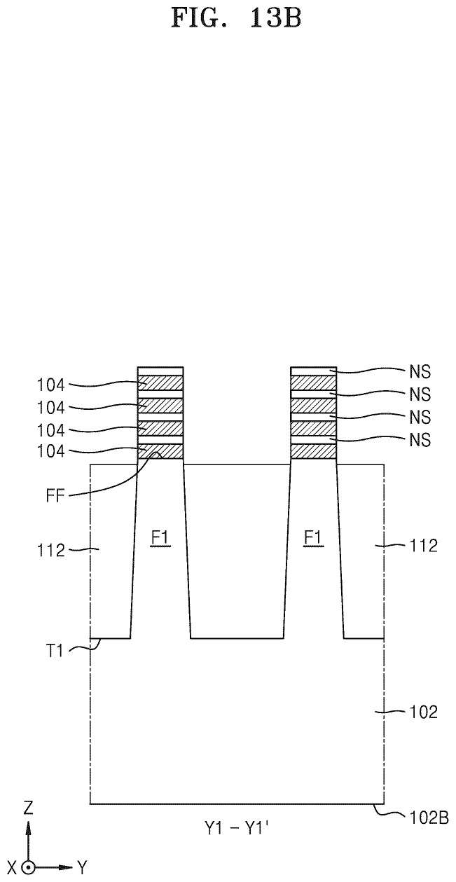

Referring to FIGS. 13A and 13B, a device isolation film 112 may be formed on the resultant structure of FIGS. 12A and 12B. The device isolation film 112 may be formed to fill the plurality of trench regions TI and sidewalls of each of the plurality of fin-type active regions F1. The device isolation film 112 may be formed with a process such as a chemical vapor deposition (CVD) process and/or a spin-on-glass (SOG) process; example embodiments are not limited thereto.

The formation of the device isolation film 112 may include forming an insulating film having such a sufficient thickness as to fill the plurality of trench regions T1 on the resultant structure of FIGS. 12A and 12B, planarizing the obtained resultant structure to expose a top surface of the mask pattern MP1 with a planarization process such as an etch-back process and/or a chemical mechanical planarization (CMP) process, removing the exposed mask pattern MP1, and performing a recess process of removing a portion of the insulating film. Thus, the device isolation film 112 including the remaining portion of the insulating film may be formed. After the device isolation film 112 is formed, a stack structure including the plurality of sacrificial semiconductor layers 104 and the plurality of nanosheet semiconductor layers NS, which remain on the substrate 102, may protrude over a top surface of the device isolation film 112, and a top surface of an uppermost one of the plurality of nanosheet semiconductor layers NS may be exposed.

Referring to FIGS. 14A, 14B, and 14C, a plurality of dummy gate structures DGS may be formed on the resultant structure of FIGS. 13A and 13B. Each of the plurality of dummy gate structures DGS may be formed to extend lengthwise in a second lateral direction (Y direction). Each of the plurality of dummy gate structures DGS may include a dummy oxide film D122, a dummy gate layer D124, and a capping layer D126, which are sequentially stacked on the stack structure including the plurality of sacrificial semiconductor layers 104 and the plurality of nanosheet semiconductor layers NS. In some example embodiments, the dummy gate layer D124 may include polysilicon such as doped or undoped polysilicon, and the capping layer D126 may include a silicon nitride film.

As shown in FIG. 14A, a plurality of insulating spacers 118 may be respectively formed on both sidewalls of the plurality of dummy gate structures DGS. A portion of each of the plurality of sacrificial semiconductor layers 104 and the plurality of nanosheet semiconductor layers NS and a portion of the fin-type active region F1 may be etched by using the plurality of dummy gate structures DGS and the plurality of insulating spacers 118 as etch masks. Thus, the plurality of nanosheet semiconductor layers NS may be divided into a plurality of nanosheet stacks NSS including the first to fourth nanosheets N1, N2, N3, and N4, and a plurality of recesses R1 may be formed in in upper portions of the fin-type active region F1. Widths of the first to fourth nanosheets N1, N2, N3, and N4 in the first lateral direction (X direction) may be defined by the plurality of recesses R1.

The plurality of recesses R1 may be formed by using a dry etching process such as a reactive ion etch (RIE) process, a wet etching process using one or more wet chemical etchants, or a combination of a dry etching process and a wet etching process. During the formation of the plurality of insulating spacers 118 and the plurality of recesses R1, as shown in FIG. 14C, a plurality of side insulating spacers 119 may be formed adjacent to the plurality of recesses R1 on the device isolation film 112 on both sides of each of the fin-type active region F1 in the second lateral direction (Y direction).

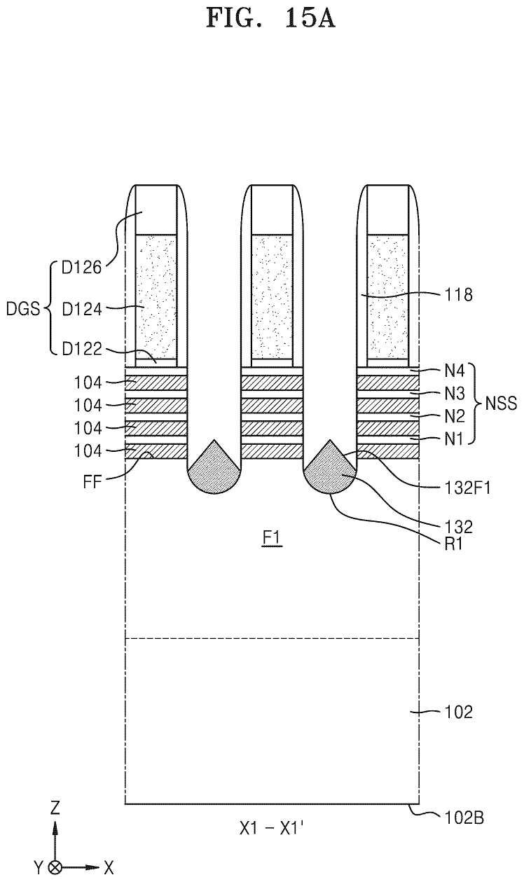

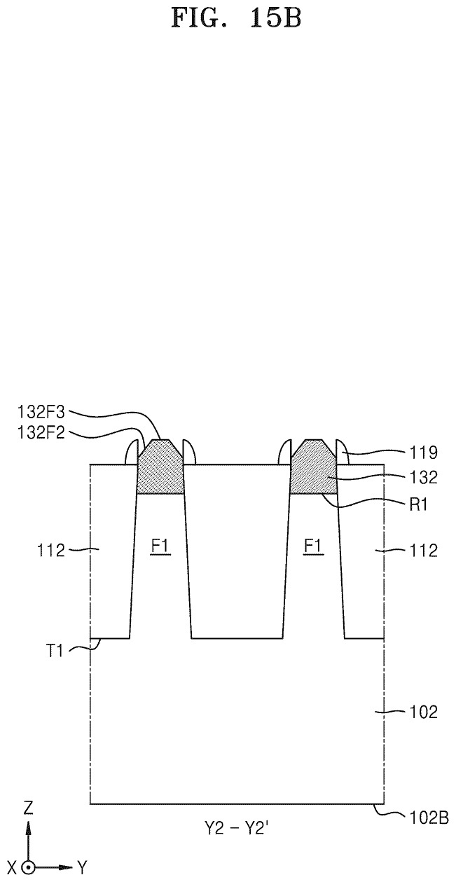

Referring to FIGS. 15A and 15B, a semiconductor material may be epitaxially grown in a bottom-up manner from a surface of the fin-type active region FA, which is exposed at a bottom surface of the recess R1, to form a bottom epitaxial layer 132. To form the bottom epitaxial layer 132 in a desired shape, one or more of various process variables such as one or more of pressure, gas flow rate, and temperature may be appropriately controlled in the epitaxial growth process.

In some example embodiments, to form the bottom epitaxial layer 132, at least one of a low-pressure chemical vapor deposition (LPCVD) process, a selective epitaxial growth (SEG) process, or a cyclic deposition and etching (CDE) process may be performed by using source materials including an element semiconductor precursor. The element semiconductor precursor may include an element, such as silicon (Si) and germanium (Ge).

In some example embodiments, the bottom epitaxial layer 132 may include a SiGe layer doped with boron (B) or having boron incorporated therein. In this case, to form the bottom epitaxial layer 132, boron (B) ions may be doped in-situ while supplying a Si source and a Ge source onto the substrate 102. Silane (SiH₄), disilane (Si₂H₆), trisilane (Si₃H₈), and/or dichlorosilane (SiH₂Cl₂) may be used as the Si source, without being limited thereto. Germane (GcH₄), digermane (Gc₂H₆), trigermane (Ge₃H₈), tetragermane (Ge₄H₁₀), and/or dichlorogermane (Ge₂H₂Cl₂) may be used as the Ge source, without being limited thereto. Diborane (B₂H₆), triborane, tetraborane, and/or pentaborane may be used as the B source, without being limited thereto.

In some example embodiments, the bottom epitaxial layer 132 may include a Si layer doped with phosphorus (P). In this case, to form the bottom epitaxial layer 132, phosphorus (P) ions may be doped in-situ while supplying a Si source onto the substrate 102. The Si source may be selected from the materials described above. Phosphine (PH₃) gas may be used as the phosphorus (P) ion source, without being limited thereto.

In some example embodiments, as shown in FIGS. 15A and 15B, the bottom epitaxial layer 132 may be formed to have an upper surface including a first facet 132F1 having a {111} plane orientation, a second facet 132F2 having a {111} plane orientation, and a third facet 132F3 having a {100} plane orientation.

In some example embodiments, unlike shown in FIGS. 15A and 15B, when an epitaxial growth process is performed to form the bottom epitaxial layer 132, process conditions (e.g., one or more of temperature, pressure, a type of the Si source, and a flow rate of supply gas) may be controlled, and/or additional processes (e.g., an etch-back process and/or chemical treatment) may be performed during and/or after the epitaxial growth process. Thus, the formation of facets in the bottom epitaxial layer 132 may be suppressed. In this case, as shown in FIG. 4, the bottom epitaxial layer 232 having an upper surface including a ridge portion 232P with a curved surface may be obtained.

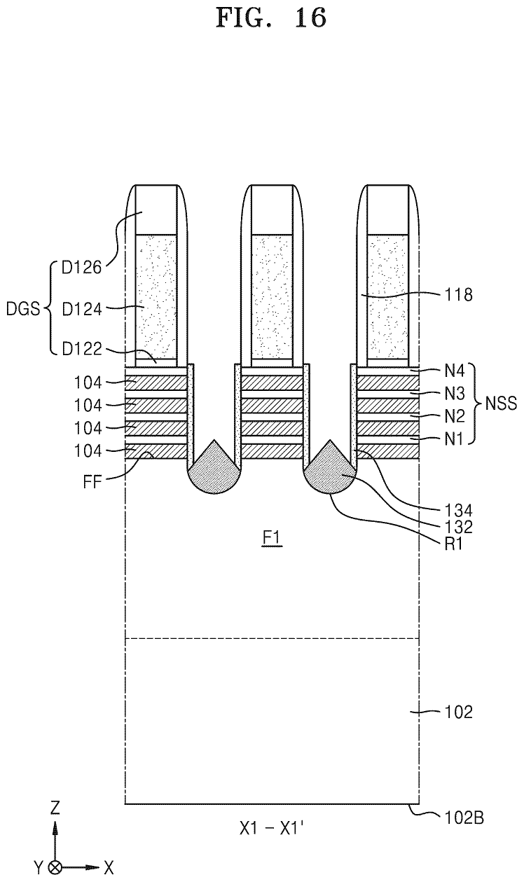

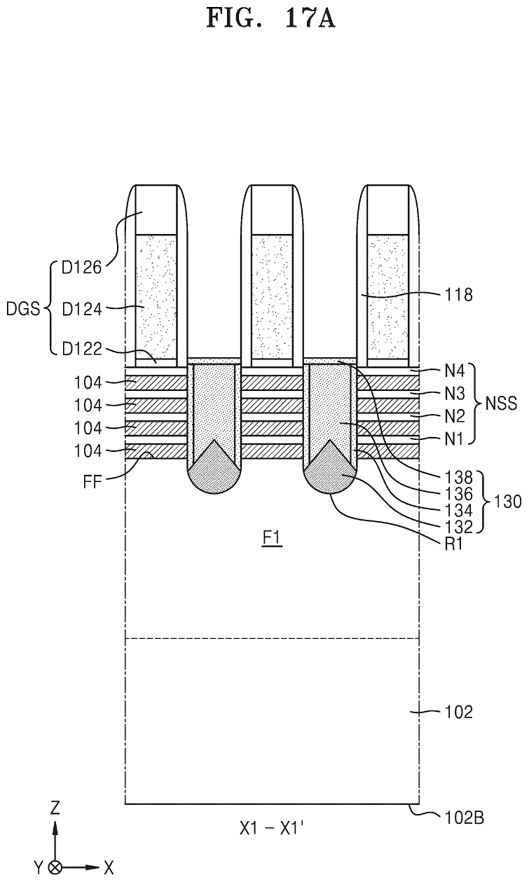

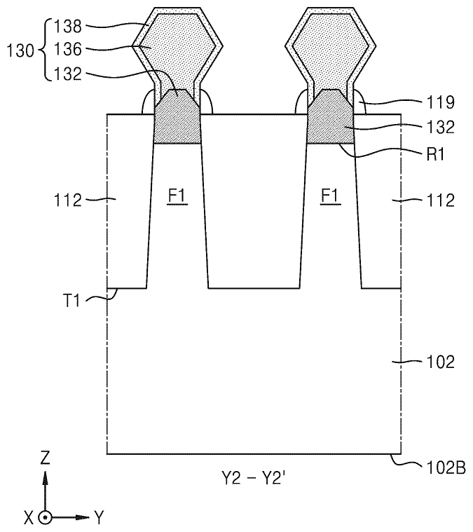

Referring to FIG. 16, in the resultant structure of FIGS. 15A and 15B, a cyclical epitaxial deposition and etching process may be performed using a difference in epitaxial growth rate and/or a difference in etch rate between a crystal plane (e.g., a {110} crystal plane) of a sidewall of the stack structure including the plurality of sacrificial semiconductor layers 104 and the plurality of nanosheet semiconductor layers NS, which are respectively exposed inside the plurality of recesses R1, and a crystal plane (e.g., a {111} crystal plane) of the first facet 132F1 of the bottom epitaxial layer 132. Here, the cyclical epitaxial deposition and etching process may include alternately repeating an epitaxial growth process and an etching process a plurality of times. Thus, a semiconductor layer may be selectively grown only on the sidewall of the stack structure including the plurality of sacrificial semiconductor layers 104 and the plurality of nanosheet semiconductor layers NS, and thus, a blocking epitaxial layer 134 may be formed to cover the sidewall of the stack structure. In this case, the epitaxial growth process and the etching process may be alternately repeated a plurality of times so as to satisfy a condition where an epitaxial growth rate on the {110} crystal plane is greater than an cpitaxial growth rate on the {111} crystal plane and a condition where the epitaxial growth rate on the {111} crystal plane is greater than the epitaxial growth rate on the {110} crystal plane.

In some example embodiments, a process similar to that described with reference to FIG. 16 may be performed, and thus, a first blocking epitaxial layer 334A and a second blocking epitaxial layer 334B, which are shown in FIG. 5, may be sequentially formed instead of the blocking epitaxial layer 134. For example, the first blocking epitaxial layer 334A may include a silicon (Si) layer doped with arsenic (As), and the second blocking epitaxial layer 334B may include a Si layer doped with phosphorus (P). In this case, to form the first blocking epitaxial layer 334A, while a cyclical epitaxial deposition and etching process is being performed a plurality of times, arsenic (As) ions may be doped in-situ while supplying a Si source onto the substrate 102 to perform an epitaxial deposition process. Arsine (AsH₃) gas may be used as the arsenic (As) ion source, without being limited thereto. To form the second blocking epitaxial layer 334B, while a cyclical epitaxial deposition and etching process is being performed a plurality of times, phosphorus (P) ions may be doped in-situ while supplying a Si source onto the substrate 102 to perform an epitaxial deposition process. In some example embodiments, alternatively to or in addition to in-situ incorporation of dopants, an implantation process such as an ion implantation process may be performed to dope the epitaxial layers; example embodiments are not limited thereto.

Referring to FIGS. 17A and 17B, a main epitaxial layer 136 and a capping layer 138 may be sequentially formed on the resultant structure on which the process described with reference to FIG. 16 has been performed. To form the main epitaxial layer 136 and the capping layer 138, processes that are similar to the epitaxial growth process described with reference to FIGS. 15A and 15B may be performed. However, the main epitaxial layer 136 may be formed to fill the remaining space of the recess R1 that is defined by the bottom epitaxial layer 132 and the blocking epitaxial layer 334. The capping layer 138 may be formed to cover a top surface of each of the blocking epitaxial layer 334 and the main epitaxial layer 136. In some example embodiments, the process of forming the capping layer 138 may be omitted.

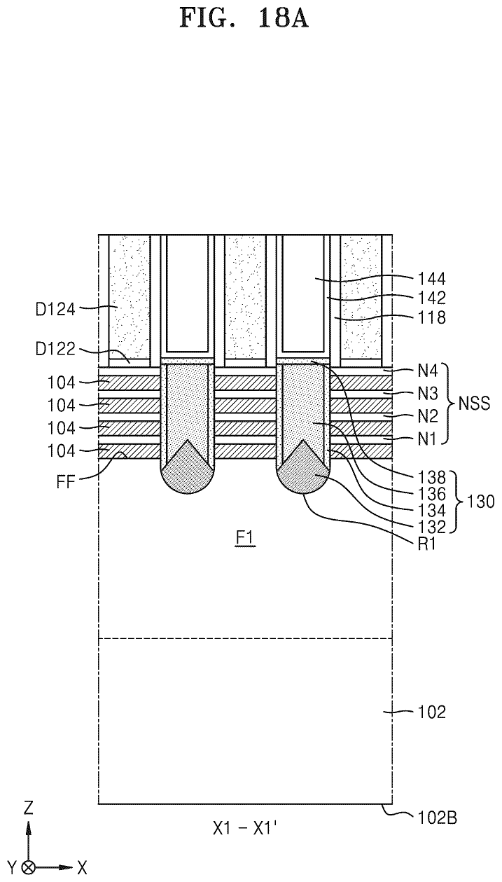

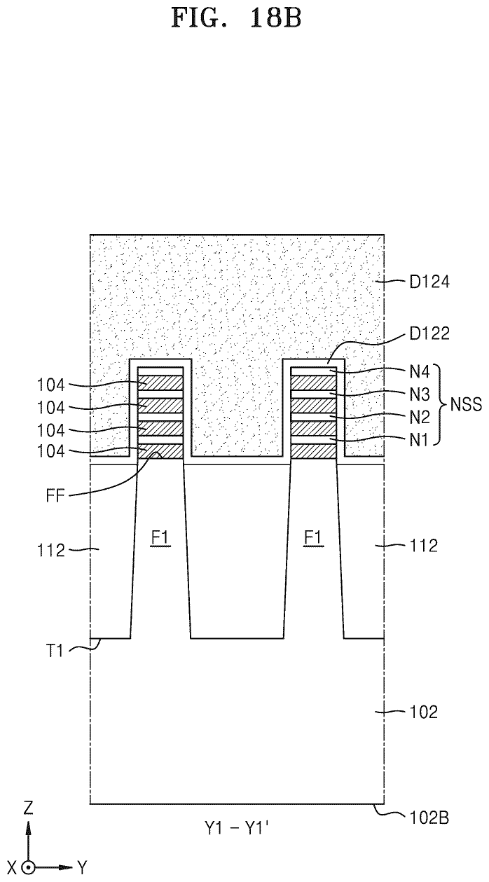

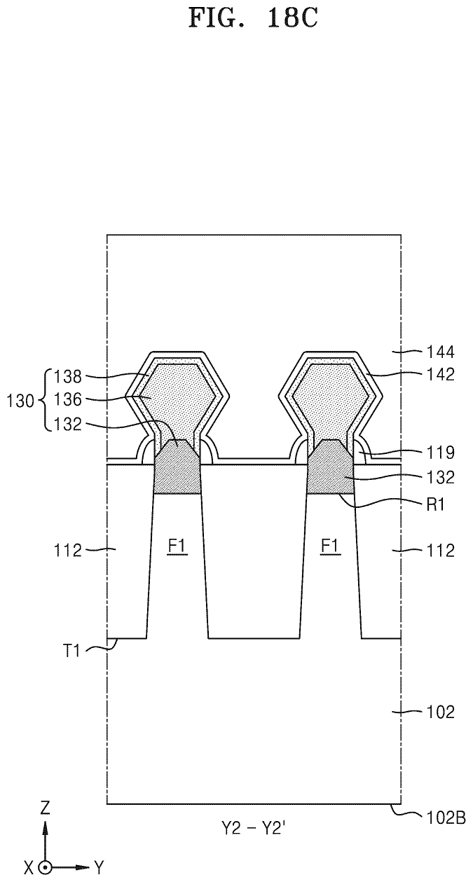

Referring to FIGS. 18A, 18B, and 18C, an insulating liner 142 may be formed to cover the resultant structure in which a plurality of source/drain regions 130 are formed, and an inter-gate dielectric film 144 may be formed on the insulating liner 142. A portion of each of the insulating liner 142 and the inter-gate dielectric film 144 may be etched to expose top surfaces of a plurality of capping layers (refer to D126 in FIG. 17A). Thereafter, the plurality of capping layers D126 may be removed to expose the dummy gate layer D124, and the insulating liner 142 and the inter-gate dielectric film 144 may be partially removed such that a top surface of the inter-gate dielectric film 144 becomes at substantially the same level as a top surface of the dummy gate layer D124.

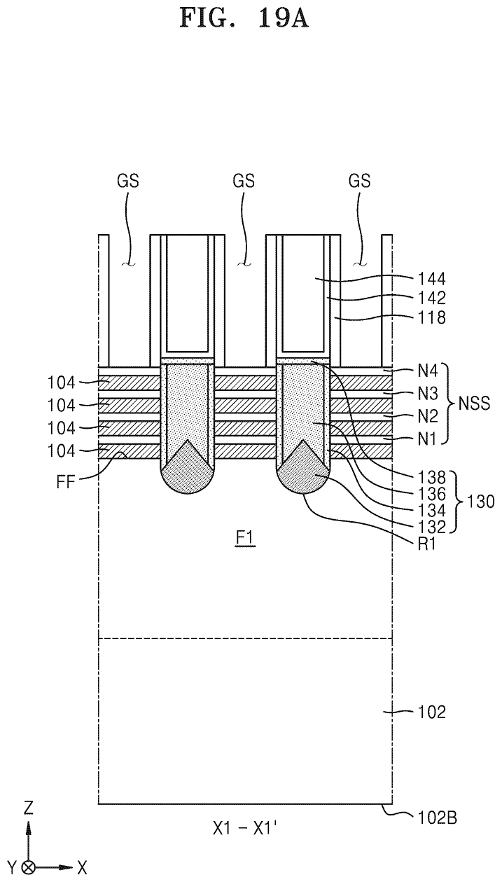

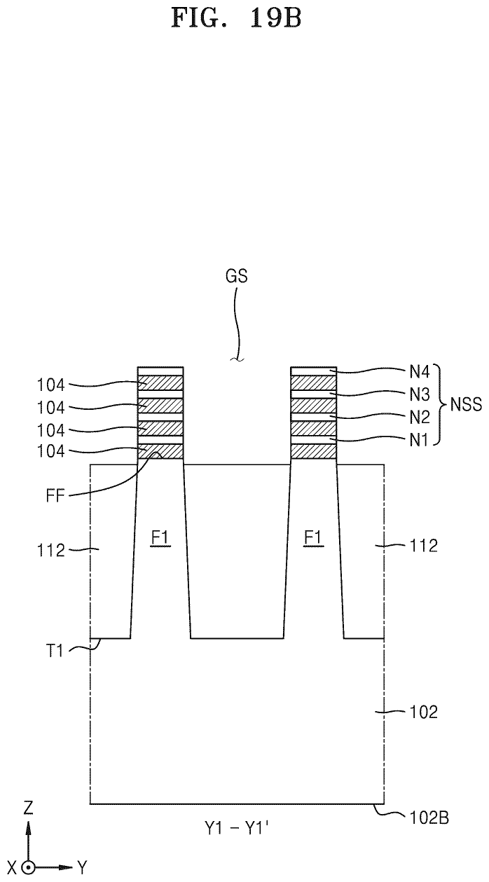

Referring to FIGS. 19A and 19B, the dummy gate layer D124 and the dummy oxide film D122 may be removed from the resultant structure of FIGS. 18A, 18B, and 18C to prepare a gate space GS.

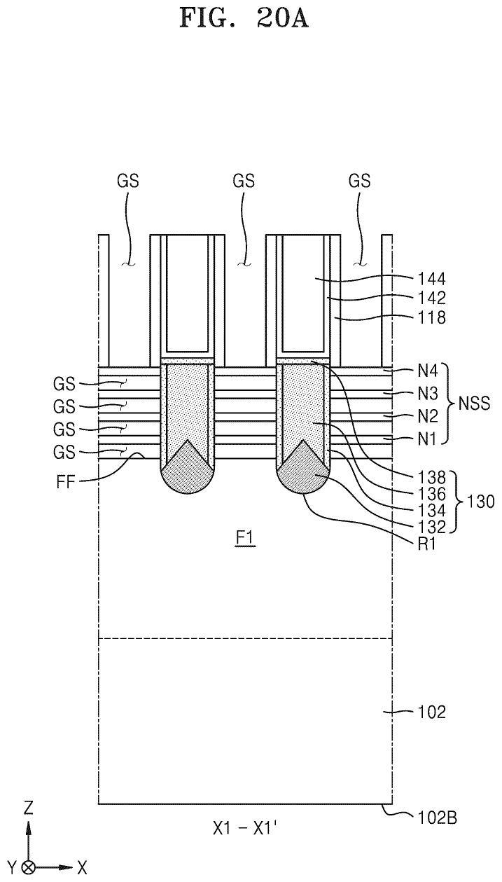

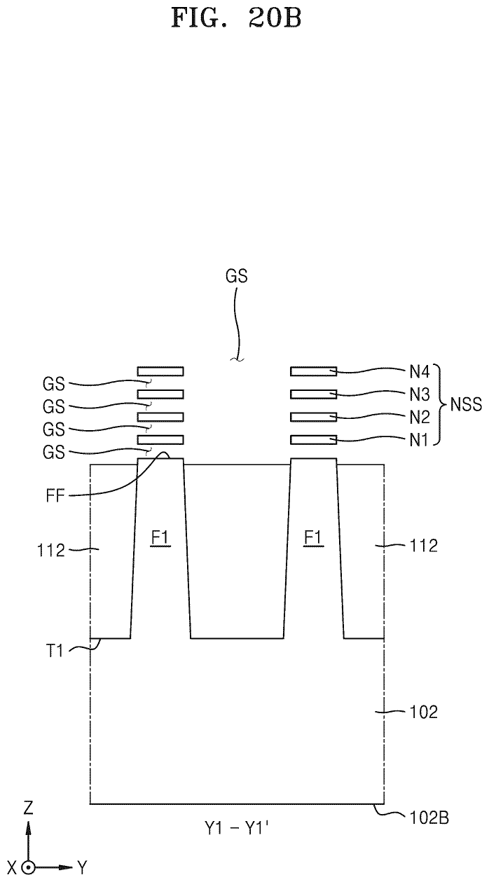

Referring to FIGS. 20A and 20B, in the resultant structure of FIGS. 19A and 19B, the plurality of sacrificial semiconductor layers 104 remaining on the substrate 102 may be selectively removed through the gate space GS. Thus, the gate space GS may extend to respective spaces between the first to fourth nanosheets N1, N2, N3, and N4 and a space between the first nanosheet N1 and the fin top surface FF of the fin-type active region F1.

In some example embodiments, to selectively remove the plurality of sacrificial semiconductor layers 104, etch selectivities of each of the first to fourth nanosheets N1, N2, N3, and N4 and fin-type active region F1 with respect to the plurality of sacrificial semiconductor layers 104 may be used. A liquid and/or a gaseous etchant may be used to selectively remove the plurality of sacrificial semiconductor layers 104. In some example embodiments, to selectively remove the plurality of sacrificial semiconductor layers 104, a CH₃COOH-based etchant, for example, an etchant including a mixture of CH₃COOH, HNO₃, and HF or an etchant including a mixture of CH₃COOH, H₂O₂, and HF may be used, without being limited thereto.

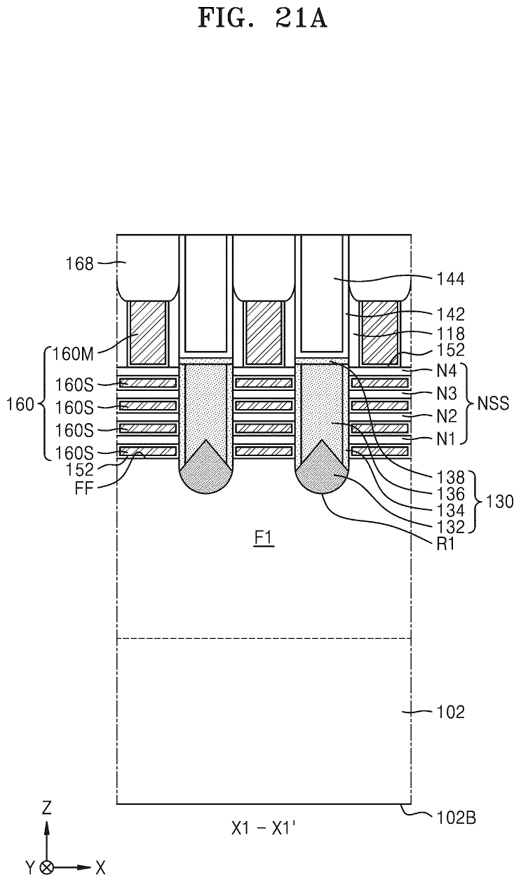

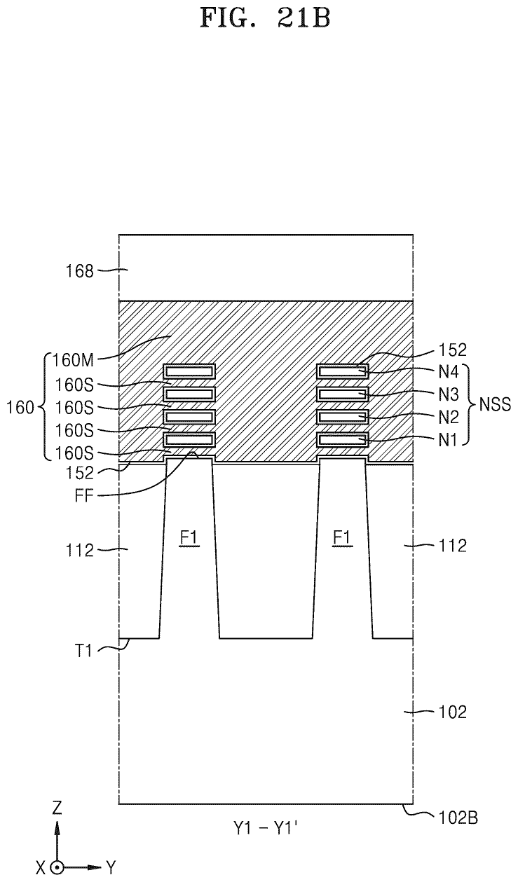

Referring to FIGS. 21A and 21B, in the resultant structure of FIGS. 20A and 20B, a gate dielectric film 152 may be formed to cover respective exposed surfaces of the first to fourth nanosheets N1, N2, N3, and N4 and the fin-type active region F1. The gate dielectric film 152 may be formed using an atomic layer deposition (ALD) process; however, example embodiments are not limited thereto.

Afterwards, a gate line 160 filling the gate space (refer to GS in FIGS. 20A and 20B) may be formed on the gate dielectric film 152. Thereafter, a height of each of the gate line 160, the gate dielectric film 152, and the insulating spacer 118 may be reduced by removing a portion of each of the gate line 160, the gate dielectric film 152, and the insulating spacer 118 from a top surface of each thereof, and a plurality of capping insulating patterns 168 may be formed to cover the top surface of each of the gate line 160, the gate dielectric film 152, and the insulating spacer 118.

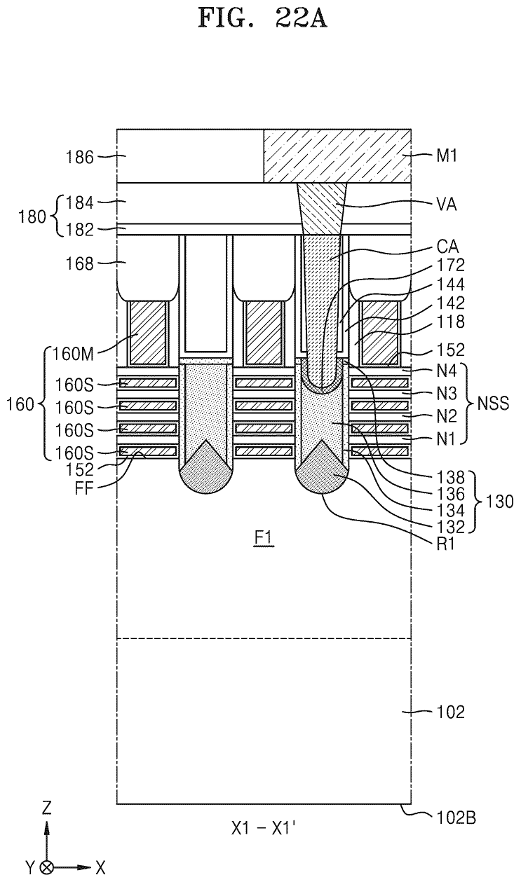

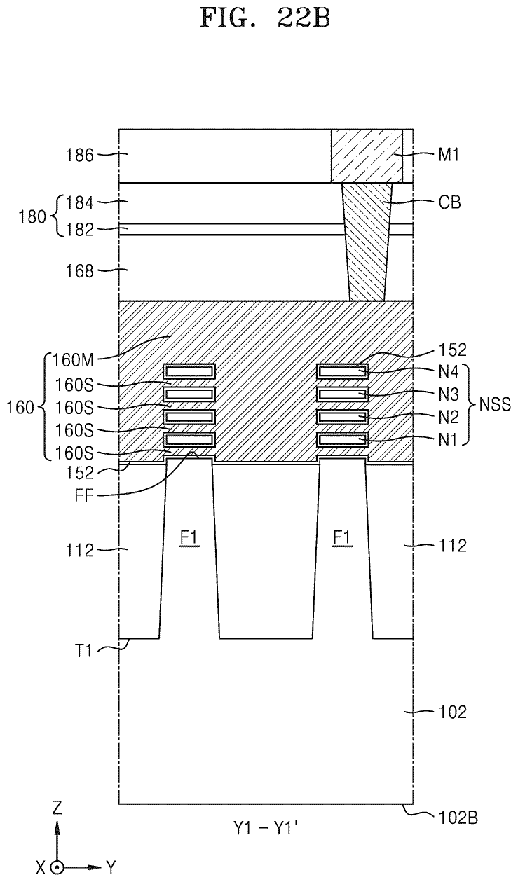

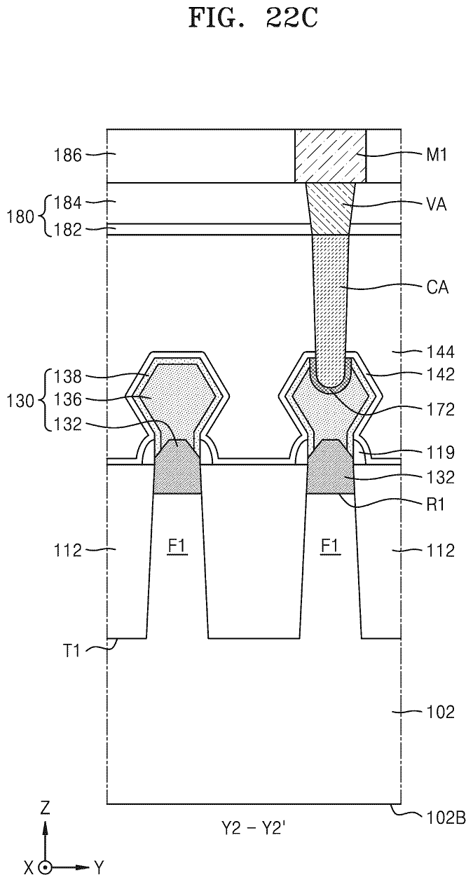

Referring to FIGS. 22A, 22B, and 22C, in the resultant structure of FIGS. 21A and 21B, a source/drain contact hole exposing the source/drain region 130 may be formed between two adjacent ones of a plurality of gate lines 160, a frontside metal silicide film 172 may be formed on a surface of the source/drain region 130 through the source/drain contact hole, and a frontside source/drain contact CA filling the source/drain contact hole may be formed on the frontside metal silicide film 172.

Subsequently, an etch stop film 182 and an upper insulating film 184 may be sequentially formed to cover a top surface of each of the frontside source/drain contact CA, the plurality of capping insulating patterns 168, and the inter-gate dielectric film 144 to form an upper insulating structure 180. Afterwards, a source/drain via contact VA and a gate contact CB may be formed. The source/drain via contact VA may pass through the upper insulating structure 180 in a vertical direction (Z direction) and be connected to the frontside source/drain contact CA. The gate contact CB may pass through the upper insulating structure 180 and the capping insulating pattern 168 in the vertical direction (Z direction) and be connected to the gate line 160. The source/drain via contact VA and the gate contact CB may be formed simultaneously or at least partly simultaneously, and/or by using separate processes. Thereafter, an interlayer insulating film 186 may be formed to cover the upper insulating structure 180, and a plurality of upper wiring layers M1 may be formed to pass through the interlayer insulating film 186. The plurality of upper wiring layers M1 may include an upper wiring layer M1 connected to the source/drain via contact VA and an upper wiring layer M1 connected to the gate contact CB. Afterwards, a frontside wiring structure (not shown) may be formed on the interlayer insulating film 186 and the plurality of upper wiring layers M1.

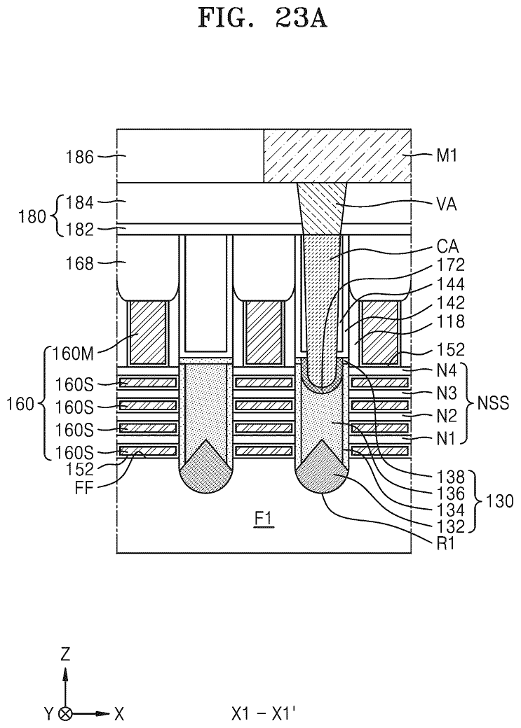

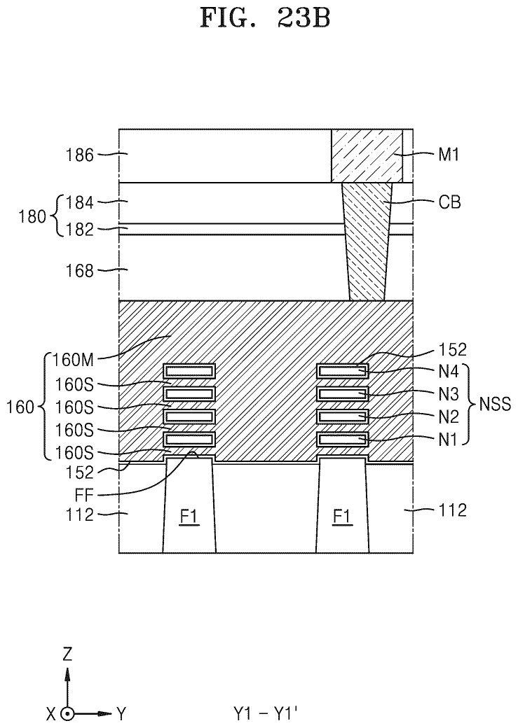

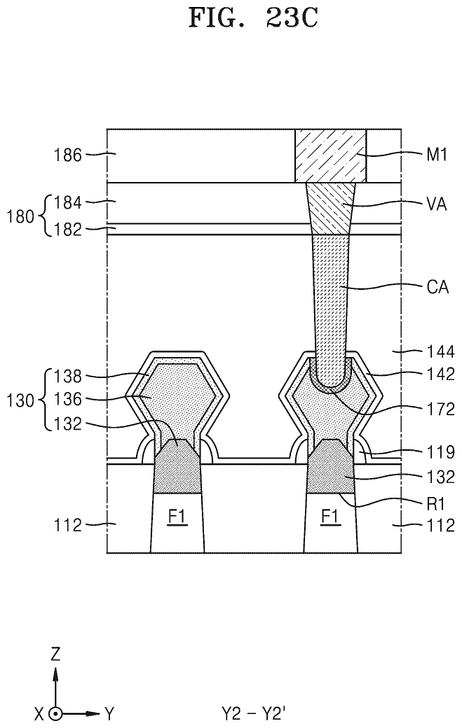

Referring to FIGS. 23A, 23B, and 23C, in the resultant structure of FIGS. 22A, 22B, and 22C, portions of the substrate 102 may be removed from the backside surface 102B of the substrate 102 to expose the plurality of fin-type active regions F1 and the device isolation film 112. A portion of each of the plurality of fin-type active regions F1 and the device isolation film 112 that are exposed may be further removed to reduce a thickness of each of the plurality of fin-type active regions F1 and the device isolation film 112 in the vertical direction (Z direction). In some example embodiments, a front side of the substrate may be passivated or protected by depositing a protective film prior to removal of the backside (not shown). Example embodiments are not limited thereto.

In some example embodiments, the process of removing the substrate 102 and the process of removing the portion of each of the plurality of fin-type active regions F1 and the device isolation film 112 may be performed using at least one process selected from a mechanical grinding process, a chemical mechanical polishing (CMP) process, a wet etching process, and a combination thereof.

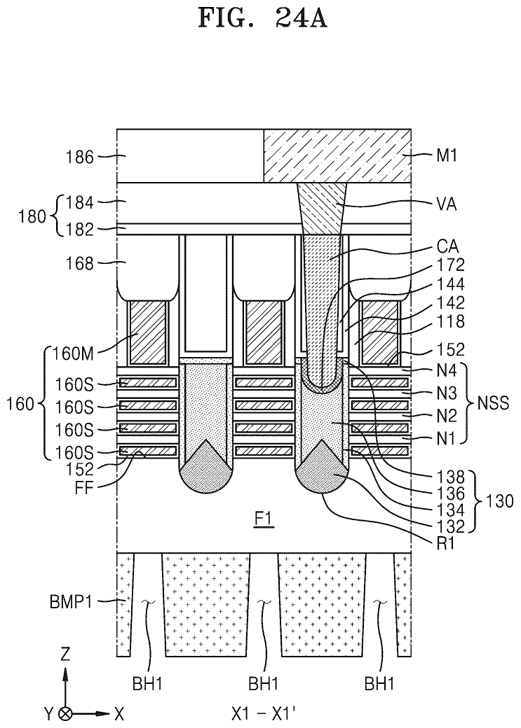

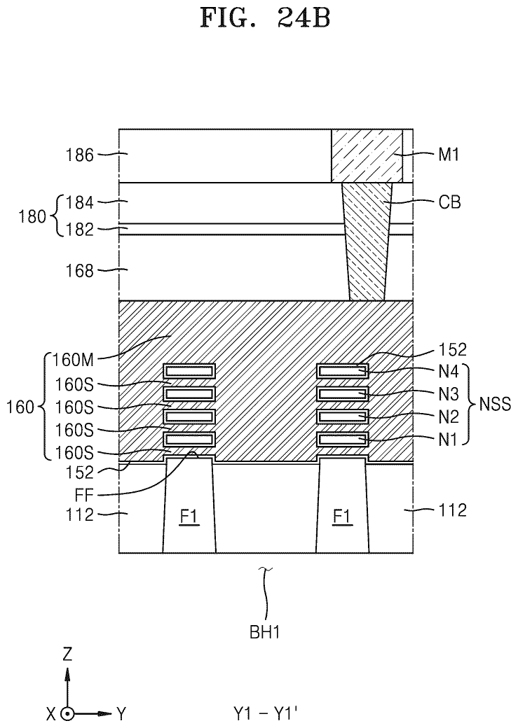

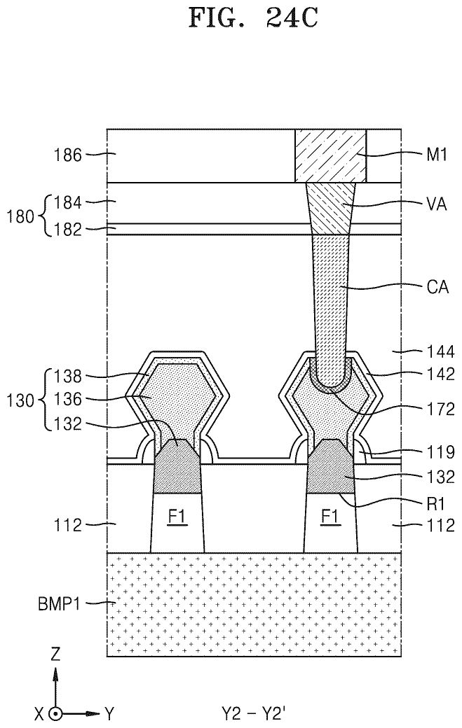

Referring to FIGS. 24A, 24B, and 24C, in the resultant structure of FIGS. 23A, 23B, and 23C, a first backside mask pattern BMP1 may be formed on the backside surface (refer to 102B in FIGS. 22A to 22C) at which the plurality of fin-type active regions F1 and the device isolation film 112 are exposed. The first backside mask pattern BMP1 may have a plurality of line-shaped openings BH1, which extend lengthwise in the second lateral direction (Y direction). A portion of each of the plurality of fin-type active regions F1 and the device isolation film 112 may be exposed through the plurality of line-shaped openings BH1 of the first backside mask pattern BMP1. In some example embodiments, the first backside mask pattern BMP1 may include a spin-on-hard mask (SOH) material, without being limited thereto.

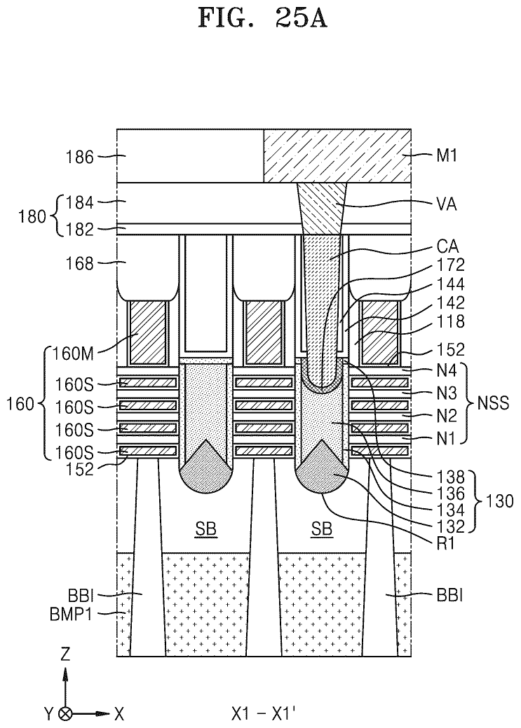

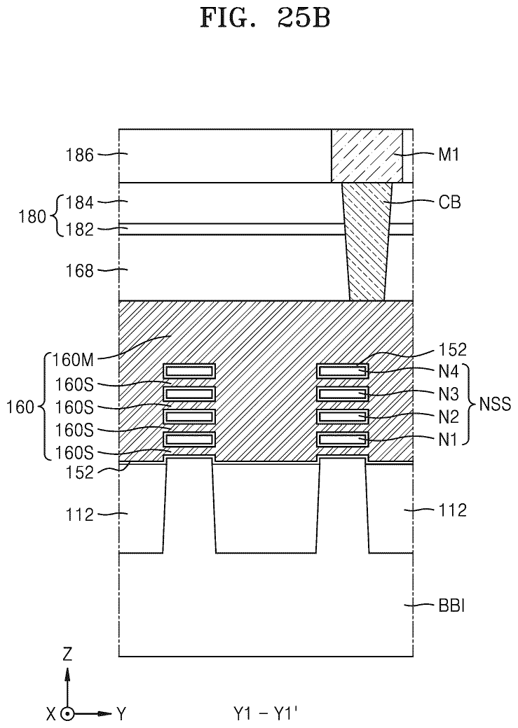

Referring to FIGS. 25A and 25B, in the resultant structure of FIGS. 24A, 24B, and 24C, the plurality of fin-type active regions F1 may be selectively etched using the first backside mask pattern BMP1 as an etch mask, and thus, a plurality of first vertical holes SHI may be formed to expose the gate dielectric film 152. When the plurality of first vertical holes SHI are formed, each of the plurality of fin-type active regions F1 may be divided into a plurality of semiconductor blocks SB.

Thereafter, a plurality of backside bulk insulating films BBI may be formed to fill the plurality of first vertical holes SHI and the plurality of line-shaped openings BH1. In some example embodiments, the plurality of backside bulk insulating films BBI may be formed using an ALD process or a chemical vapor deposition (CVD) process, without being limited thereto.

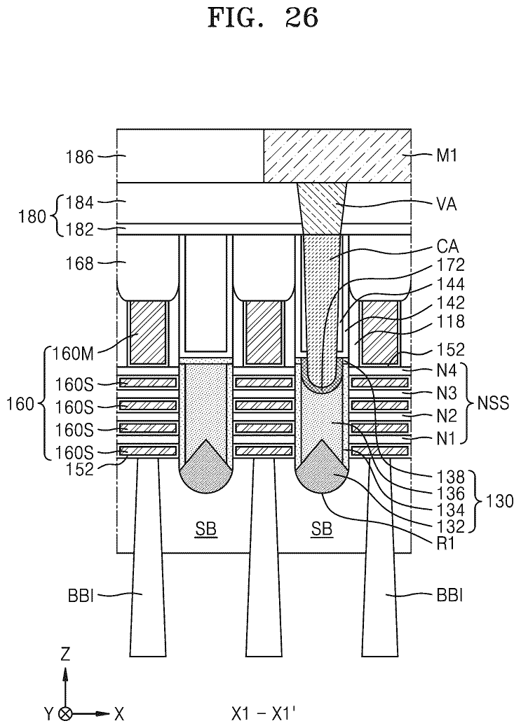

Referring to FIG. 26, the first backside mask pattern BMP1 may be removed from the resultant structure of FIGS. 25A and 25B. When the first backside mask pattern BMP1 includes a SOH material, the first backside mask pattern BMP1 may be removed using ashing and/or strip processes.

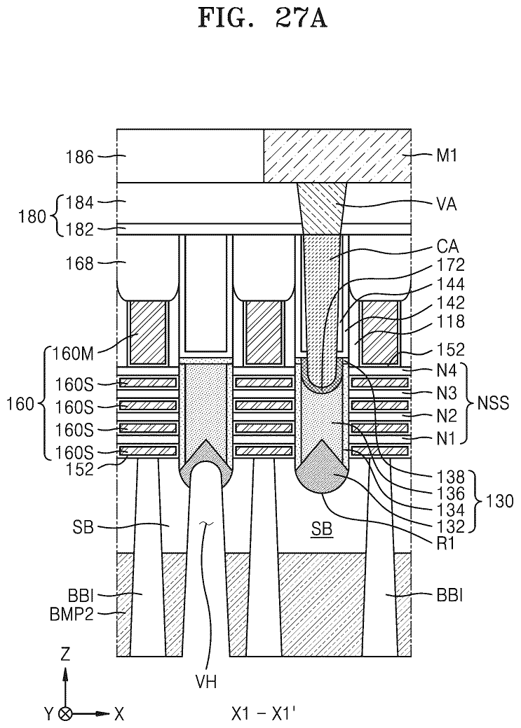

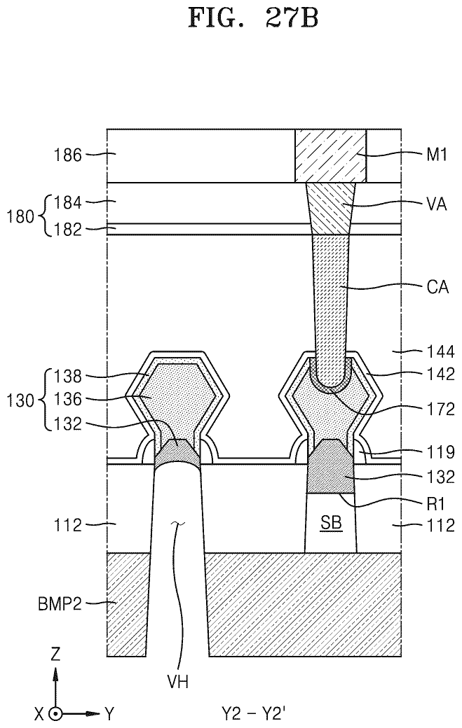

Referring to FIGS. 27A and 27B, the resultant structure of the process described with reference to FIG. 26 may be coated with a SOH material to form a planarized hardmask film. The hardmask film may be planarized to form a second backside mask pattern BMP2 having a hole exposing the semiconductor block SB. Afterwards, the semiconductor block SB may be etched by using the second backside mask pattern BMP2 as an etch mask to form a via hole VH exposing the bottom epitaxial layer 132 of the source/drain region 130. A portion of the source/drain region 130 may be etched during the formation of the via hole VH, and thus, the via hole VH may extend into the bottom epitaxial layer 132 of the source/drain region 130.

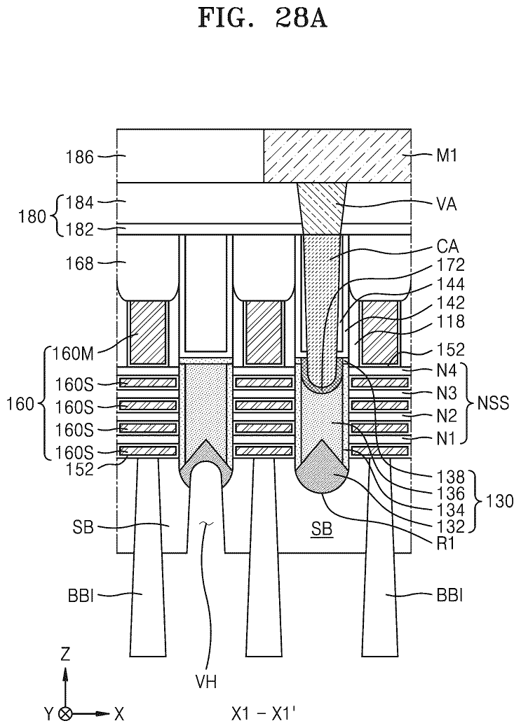

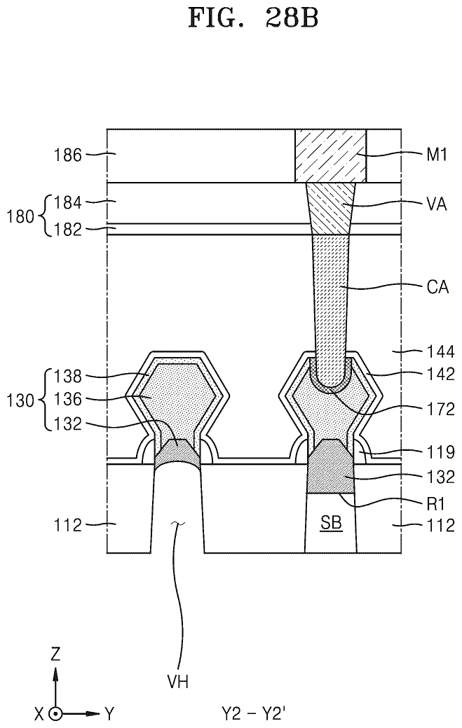

Referring to FIGS. 28A and 28B, the second backside mask pattern BMP2 may be removed from the resultant structure of FIGS. 27A and 27B. When the second backside mask pattern BMP2 includes a SOH material, the second backside mask pattern BMP2 may be removed using ashing and strip processes.

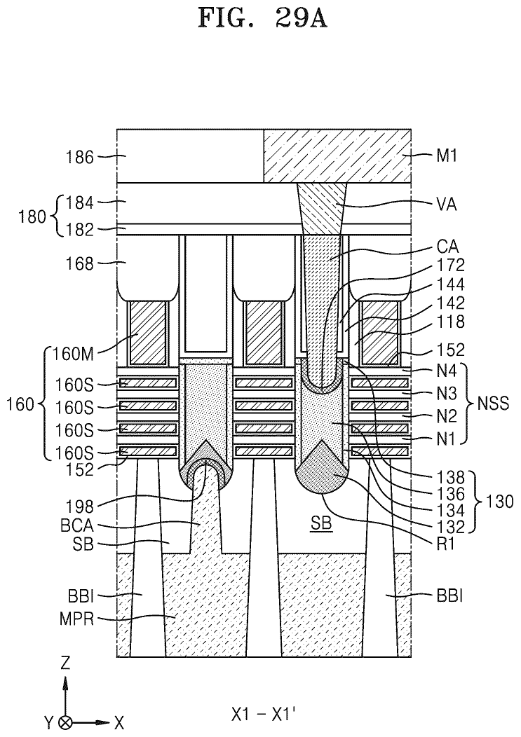

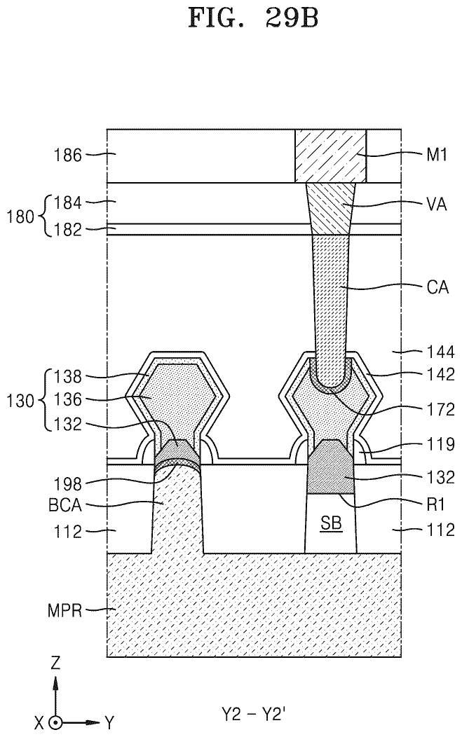

Referring to FIGS. 29A and 29B, in the resultant structure of FIGS. 28A and 28B, respective spaces between the via holes VH and the backside bulk insulating films BBI may be filled by a conductive material to form the backside via contact BCA and the backside power rail MPR, which are shown in FIGS. 3A and 3C. Thus, the IC device 100 shown in FIGS. 2 and 3A to 3E may be manufactured.

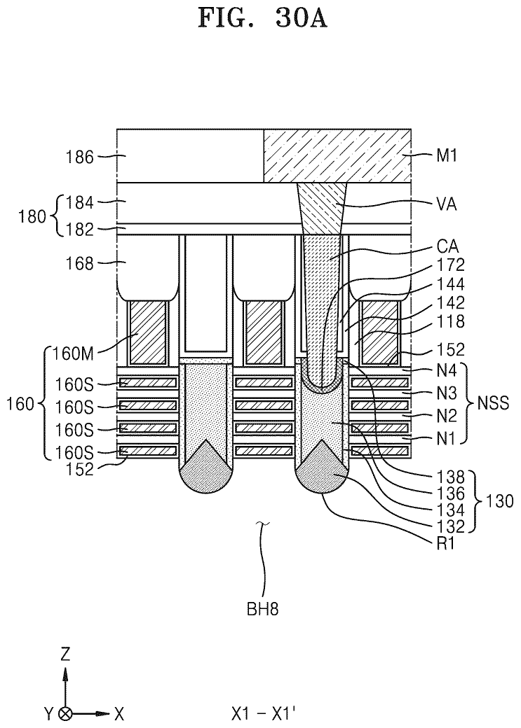

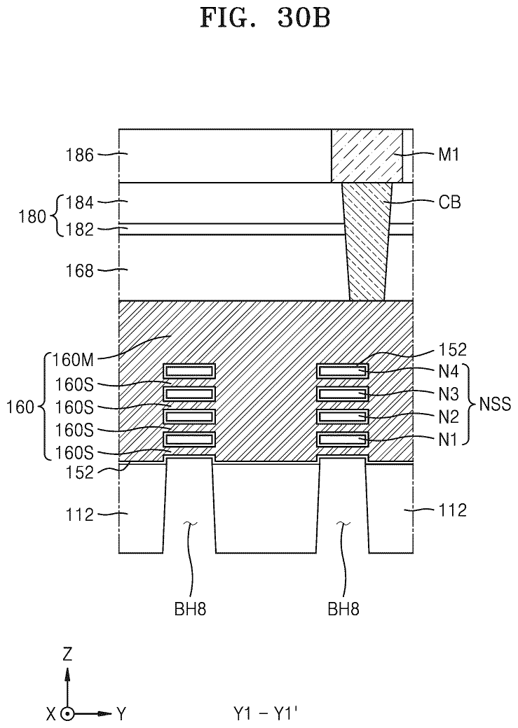

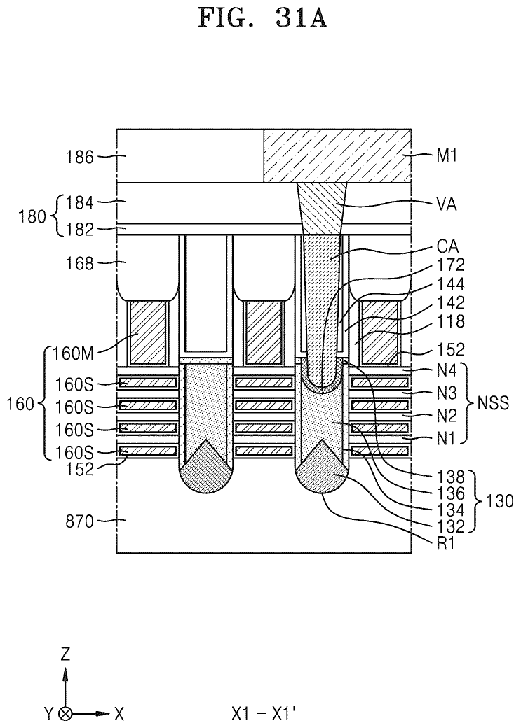

FIGS. 30A to 33 are cross-sectional views of a process sequence of a method of manufacturing an IC device, according to some example embodiments. More specifically, FIGS. 30A, 31A, 32, and 33 are cross-sectional views of example cross-sectional structures of a portion corresponding to a cross-section taken along line X1-X1′ of FIG. 2, according to the process sequence. FIGS. 30B and 31B are cross-sectional views of example cross-sectional structures of a portion corresponding to a cross-section taken along line Y1-Y1′ of FIG. 2, according to the process sequence. An example of a method of manufacturing the IC device 800 described with reference to FIG. 10 is described with reference to FIGS. 30A to 33. In FIGS. 30A to 33, the same reference numerals are used to denote the same elements as in FIGS. 2 to 10, and detailed descriptions thereof are omitted.

Referring to FIGS. 30A and 30B, the processes described with reference to FIGS. 11A to 23C may be performed. Afterwards, a plurality of fin-type active regions F1 may be removed from the resultant structure of FIGS. 23A, 23B, and 23C. As a result, portions in which the plurality of fin-type active regions F1 were located may remain as a plurality of spaces BH8.

In some example embodiments, the plurality of fin-type active regions F1 may be removed using a wet etching process. A width of each of the plurality of spaces BH8 in a second lateral direction (Y direction) may be defined by a device isolation film 112. A gate dielectric film 152 may be exposed through the plurality of spaces BH8.

Referring to FIGS. 31A and 31B, in the resultant structure of FIGS. 30A and 30B, a first backside insulating film 870 may be formed to fill the plurality of spaces BH8 and cover the device isolation film 112.

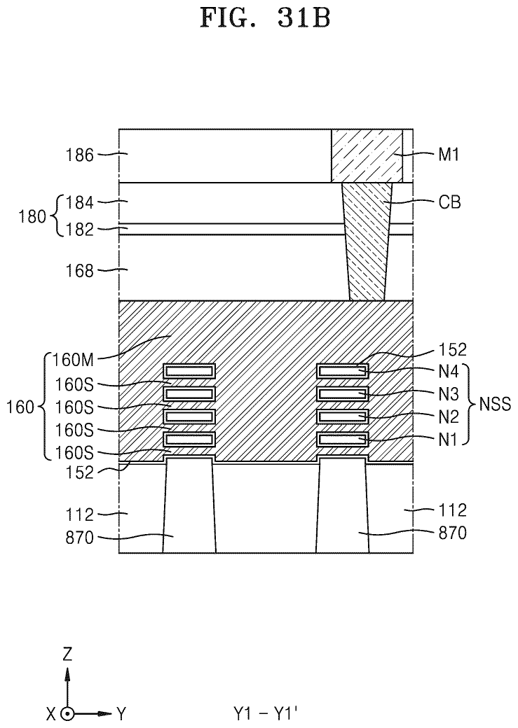

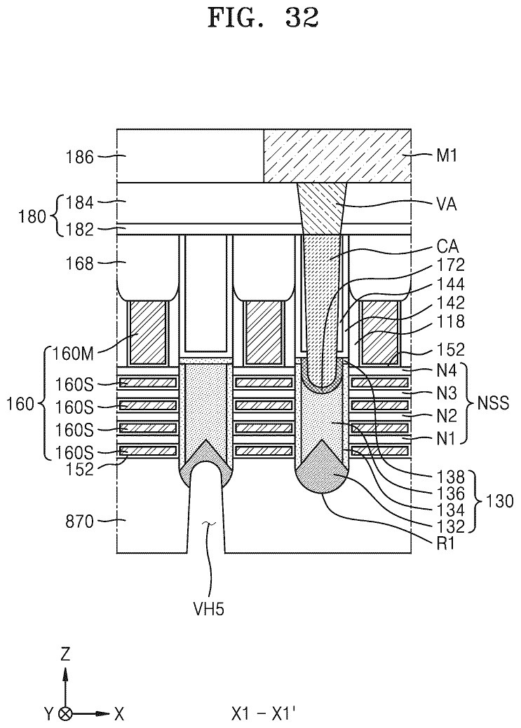

Referring to FIG. 32, in the resultant structure of FIGS. 31A and 31B, a partial region of the first backside insulating film 870 may be etched to form a via hole VH5 exposing a bottom epitaxial layer 132 of a source/drain region 130. A portion of the source/drain region 130 may be etched during the formation of the via hole VH5, and thus, the via hole VH5 may extend into the bottom epitaxial layer 132 of the source/drain region 130.

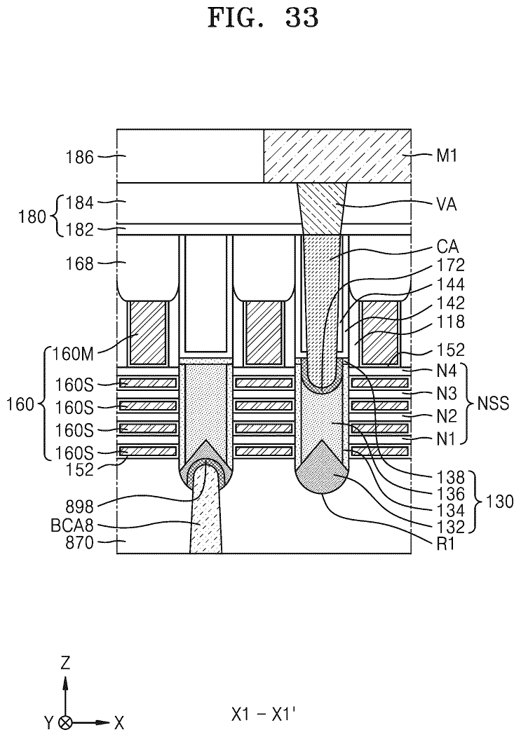

Referring to FIG. 33, in the resultant structure of FIG. 32, a backside metal silicide film 898 may be formed through the via hole VH5, and a backside via contact BCA8 may be formed to fill the via hole VH5.

Afterwards, a second backside insulating film 880 covering the backside via contact BCA8 and the first backside insulating film 870 may be formed on the resultant structure of FIG. 33, and a backside power rail MPR8 may be formed to pass through the second backside insulating film 880 in the vertical direction (Z direction). Thus, the IC device 800 shown in FIG. 10 may be manufactured.

Although the IC device 100 shown in FIGS. 2 and 3A to 3E and the method of manufacturing the IC device 800 shown in FIG. 10 have been described with reference to FIGS. 11A to 33, it will be understood that the IC devices 200, 300, 400, 500, 600, and 700 shown in FIGS. 4 to 9 and IC devices having various structures may be manufactured by applying various modifications and changes to the processes described with reference to FIGS. 11A to 33 within the scope of inventive concepts.

While inventive concepts has been particularly shown and described with reference to some example embodiments thereof, it will be understood that various changes in form and details may be made therein without departing from the spirit and scope of the following claims. Additionally example embodiments are not necessarily mutually exclusive. For example, some example embodiments may include one or more features described with reference to one or more figures, and may also include one or more other features described with reference to one or more other figures.

What is claimed is:

1. An integrated circuit device comprising:
a channel region;
a gate line surrounding the channel region;
a source/drain region adjacent to the gate line in a first lateral direction, the source/drain region contacting the channel region; and
a backside via contact passing through a portion of the source/drain region in a vertical direction from a back side of the source/drain region,
wherein the source/drain region comprises,
a bottom epitaxial layer protruding from a bottom surface of the source/drain region toward a central portion of the source/drain region in the vertical direction,
a blocking epitaxial layer contacting each of the channel region and the bottom epitaxial layer, and
a main epitaxial layer filling a space defined by the blocking epitaxial layer on the bottom epitaxial layer, wherein
a first dopant concentration of the bottom epitaxial layer is greater than a second dopant concentration of the blocking epitaxial layer and is greater than or equal to a third dopant concentration of the main epitaxial layer, and
the backside via contact passes through at least a portion of the bottom epitaxial layer in the vertical direction.

2. The integrated circuit device of claim 1, further comprising:
a backside metal silicide film between the source/drain region and the backside via contact,
wherein the backside via contact is connected to the source/drain region through the backside metal silicide film, and
the backside metal silicide film contacts the bottom epitaxial layer.

3. The integrated circuit device of claim 1, wherein the main epitaxial layer is in contact with each of the bottom epitaxial layer and the blocking epitaxial layer.

4. The integrated circuit device of claim 1, wherein the main epitaxial layer is in contact with only the blocking epitaxial layer, from among the bottom epitaxial layer and the blocking epitaxial layer.

5. The integrated circuit device of claim 1, wherein
the bottom epitaxial layer has an upper surface inclined in a direction towards a top surface of a front side of the source/drain region toward the central portion of the source/drain region in the first lateral direction, and
the top surface of the bottom epitaxial layer comprises a first facet having a {111} plane orientation.

6. The integrated circuit device of claim 5, wherein the bottom epitaxial layer further comprises:
a second facet inclined in a direction towards the top surface of the front side of the source/drain region toward the central portion of the source/drain region in a second lateral direction, wherein the second lateral direction is perpendicular to each of the first lateral direction and the vertical direction; and
a third facet extending in the second lateral direction,
wherein the second facet has a {111} plane orientation, and
the third facet has a {100} plane orientation.

7. The integrated circuit device of claim 1, wherein
the bottom epitaxial layer has an upper surface having a convex shape, which gets close to a top surface of a front side of the source/drain region toward the central portion of the source/drain region in the first lateral direction, and
the top surface of the bottom epitaxial layer comprises a ridge portion with a curved surface.

8. The integrated circuit device of claim 1, wherein
a width of the blocking epitaxial layer in the first lateral direction is not constant in the vertical direction, and
the blocking epitaxial layer has a greatest width in the first lateral direction at a portion of the blocking epitaxial layer, which contacts the bottom epitaxial layer.

9. The integrated circuit device of claim 1, wherein
the bottom epitaxial layer comprises a first facet that is inclined in a direction close to a top surface of a front side of the source/drain region toward the central portion of the source/drain region in the first lateral direction, and
a portion of the first facet of the bottom epitaxial layer is in contact with the blocking epitaxial layer, and another portion of the first facet of the bottom epitaxial layer is in contact with the main epitaxial layer.

10. The integrated circuit device of claim 1, wherein
the bottom epitaxial layer comprises a first facet that is inclined in a direction close to a top surface of a front side of the source/drain region toward the central portion of the source/drain region in the first lateral direction, and
the first facet of the bottom epitaxial layer contacts the blocking epitaxial layer without contacting the main epitaxial layer.

11. The integrated circuit device of claim 1, further comprising:
a backside metal silicide film between the source/drain region and the backside via contact, wherein
the backside via contact is connected to the source/drain region through the backside metal silicide film, and
the backside via contact extends in the vertical direction to completely pass through the bottom epitaxial layer in the vertical direction and to pass through a portion of the main epitaxial layer in the vertical direction, and
the backside metal silicide film is in contact with each of the bottom epitaxial layer and the main epitaxial layer.

12. The integrated circuit device of claim 1, wherein the blocking epitaxial layer comprises:
a first blocking epitaxial layer contacting the channel region; and
a second blocking epitaxial layer apart from the channel region with the first blocking epitaxial layer therebetween, the second blocking epitaxial layer contacting the main epitaxial layer,
wherein the first blocking epitaxial layer and the second blocking epitaxial layer comprise different dopants from each other.

13. An integrated circuit device comprising:
a plurality of channel regions apart from each other in a first lateral direction;
a plurality of gate lines surrounding the plurality of channel regions, each of the plurality of gate lines extending lengthwise in a second lateral direction, wherein the second lateral direction is perpendicular to the first lateral direction;
a plurality of source/drain regions, each of which is between two adjacent ones of the plurality of gate lines; and
a backside via contact passing through a portion of a first source/drain region in a vertical direction from a back side of the first source/drain region, wherein the first source/drain region is selected from the plurality of source/drain regions,
wherein each of the plurality of source/drain regions comprises,
a bottom epitaxial layer protruding from a bottom surface of a corresponding one of the plurality of source/drain regions toward a central portion thereof in the vertical direction,
a blocking epitaxial layer contacting a channel region adjacent thereto in the first lateral direction, from among the plurality of channel regions, and
a main epitaxial layer filling a space defined by the blocking epitaxial layer on the bottom epitaxial layer,
wherein, in each of the plurality of source/drain regions, a first dopant concentration of the bottom epitaxial layer is greater than a second dopant concentration of the blocking epitaxial layer and is greater than or equal to a third dopant concentration of the main epitaxial layer, and
the backside via contact passes through at least a portion of the bottom epitaxial layer included in the first source/drain region in the vertical direction.

14. The integrated circuit device of claim 13, further comprising:
a backside metal silicide film between the first source/drain region and the backside via contact, wherein
the backside via contact is connected to the first source/drain region through the backside metal silicide film, and
the backside metal silicide film is in contact with the bottom epitaxial layer included in the first source/drain region.

15. The integrated circuit device of claim 13, further comprising:
a frontside insulating structure covering a top surface of a front side of each of the plurality of source/drain regions;
a frontside source/drain contact passing through the frontside insulating structure in the vertical direction, the frontside source/drain contact passing through a portion of a second source/drain region in the vertical direction from a front side of the second source/drain region, wherein the second source/drain region is selected from the plurality of source/drain regions and is apart from the first source/drain region and
a frontside metal silicide film between the second source/drain region and the frontside source/drain contact,
wherein the frontside source/drain contact and the frontside metal silicide film are apart from the bottom epitaxial layer included in the second source/drain region in the vertical direction.

16. The integrated circuit device of claim 13, wherein an upper surface of the bottom epitaxial layer included in each of the plurality of source/drain regions comprises:
a first facet that is inclined in a direction close to a top surface of a front side of the corresponding one of the plurality of source/drain regions toward the central portion of the corresponding one of the plurality of source/drain regions in the first lateral direction;
a second facet that is inclined in a direction close to the top surface of the front side of the corresponding one of the plurality of source/drain regions toward the central portion of the corresponding one of the plurality of source/drain regions in a second lateral direction, wherein the second lateral direction is perpendicular to each of the first lateral direction and the vertical direction; and
a third facet extending in the second lateral direction,
wherein each of the first facet and the second facet has a {111} plane orientation, and
the third facet has a {100} plane orientation.

17. The integrated circuit device of claim 13, wherein,
in each of the plurality of source/drain regions, the bottom epitaxial layer has an upper surface having a convex shape, which gets close to a top surface of a front side of the corresponding one of the plurality of source/drain regions toward the central portion of the corresponding one of the plurality of source/drain regions in the first lateral direction, and
the top surface of the bottom epitaxial layer comprises a ridge portion with a curved surface.

18. An integrated circuit device comprising:
a plurality of channel regions apart from each other in a first lateral direction;
a plurality of gate lines respectively surrounding the plurality of channel regions, each of the plurality of gate lines extending lengthwise in a second lateral direction, wherein the second lateral direction is perpendicular to the first lateral direction;
a plurality of source/drain regions, each of which is between two adjacent ones of the plurality of gate lines;
a frontside insulating structure covering a top surface of a front side of each of the plurality of source/drain regions;
a backside via contact passing through a portion of a first source/drain region in a vertical direction from a back side of the first source/drain region, wherein the first source/drain region is selected from the plurality of source/drain regions;
a backside metal silicide film between the first source/drain region and the backside via contact;
a frontside source/drain contact passing through the frontside insulating structure in the vertical direction, the frontside source/drain contact passing through a portion of a second source/drain region in the vertical direction from a front side of the second source/drain region, wherein the second source/drain region is selected from the plurality of source/drain regions and is apart from the first source/drain region;
a frontside metal silicide film between the second source/drain region and the frontside source/drain contact,
wherein each of the plurality of source/drain regions comprises,
a bottom epitaxial layer protruding from a bottom surface of a corresponding one of the source/drain regions toward a central portion thereof in the vertical direction, the bottom epitaxial layer having a first dopant concentration,
a blocking epitaxial layer contacting each of the bottom epitaxial layer and a channel region adjacent to the blocking epitaxial layer in the first lateral direction, from among the plurality of channel regions, the blocking epitaxial layer having a second dopant concentration, wherein the second dopant concentration is lower than the first dopant concentration, and
a main epitaxial layer filling a space defined by the blocking epitaxial layer on the bottom epitaxial layer, the main epitaxial layer having a third dopant concentration, wherein the third dopant concentration is lower than or equal to the first dopant concentration,
wherein the backside via contact and the backside metal silicide film pass through at least a portion of the bottom epitaxial layer included in the first source/drain region in the vertical direction, and
the frontside source/drain contact and the frontside metal silicide film are apart from the bottom epitaxial layer included in the second source/drain region in the vertical direction.

19. The integrated circuit device of claim 18, wherein
each of the plurality of source/drain regions comprises a Si₁₋ₓGeₓ layer (x≠0) doped with a p-type dopant, and,
in each of the plurality of source/drain regions, a first germanium (Ge) content of the bottom epitaxial layer is greater than a second Ge content of the blocking epitaxial layer and is greater than or equal to a third content of the main epitaxial layer.

20. The integrated circuit device of claim 18, wherein each of the plurality of source/drain regions comprises a silicon (Si) layer doped with an n-type dopant.
